(19) United States
(12) Patent Application Publication
(10) Pub. No.: US 2025/0221197 A1
(43) Pub. Date: Jul. 3, 2025

(54) DISPLAY DEVICE AND METHOD OF MANUFACTURING DISPLAY DEVICE

(71) Applicant: Samsung Display Co., Ltd., Yongin-si (KR)

(72) Inventors: Jongryuk Park, Yongin-si (KR); Taegon Kim, Yongin-si (KR); Hyunyoung Kim, Yongin-si (KR); Mijin Yoon, Yongin-si (KR); Oukjae Lee, Yongin-si (KR)

(21) Appl. No.: 18/817,930

(22) Filed: Aug. 28, 2024

(30) Foreign Application Priority Data
Dec. 29, 2023 (KR) 10-2023-0197605

(51) Int. Cl. H10K 59/131; H10K 59/12; H10K 59/121; H10K 102/00

(52) U.S. Cl. CPC H10K 59/131; H10K 59/1201; H10K 59/1213; H10K 59/1216; H10K 2102/351

(57) ABSTRACT

A display device includes: a substrate; a first transistor including: a first semiconductor layer on the substrate; and a first gate electrode on the first semiconductor layer; a second transistor including: a second semiconductor layer on the first gate electrode; and a second gate electrode on the second semiconductor layer; an insulating structure between the first gate electrode and the second gate electrode; and a first transfer pattern at a same layer as that of the second gate electrode, electrically connected to the first gate electrode through a contact hole passing through the insulating structure, and including a first layer and a second layer on the first layer. The first layer includes a first portion in the contact hole, and a second portion outside the contact hole. A thickness of the second portion of the first layer is in a range of about 450 Å to 800 Å.

### CROSS-REFERENCE TO RELATED APPLICATION

The present application claims priority to and the benefit of Korean Patent Application No. 10-2023-0197605, filed on Dec. 29, 2023, in the Korean Intellectual Property Office, the entire disclosure of which is incorporated by reference herein.

### BACKGROUND

### 1. Field

Aspects of one or more embodiments of the present disclosure relate to a display device, and a method of manufacturing the display device.

### 2. Description of the Related Art

As the display field for visually displaying various electrical signal information has rapidly advanced, various display devices having excellent characteristics, such as thinness, reduced weight, and low power consumption, have been introduced. Among the display devices, organic light-emitting display devices in particular have attracted attention as next-generation display devices, because the organic light-emitting display devices may have a wide viewing angle, excellent contrast, and fast response speeds.

A display device includes a thin-film transistor (TFT), a capacitor, and the like as a driving circuit. The TFT may include an active layer including a channel region, a source region, and a drain region, and a gate electrode electrically insulated from the active layer by a gate insulating layer. In general, the active layer of the TFT may contain amorphous silicon or poly-silicon.

The above information disclosed in this Background section is for enhancement of understanding of the background of the present disclosure, and therefore, it may contain information that does not constitute prior art.

### SUMMARY

One or more embodiments of the present disclosure may be directed to a display device having improved display quality, and a method of manufacturing the display device. However, the aspects and features of the present disclosure are not limited thereto or thereby.

Additional aspects and features will be set forth, in part, in the description that follows, and in part, will be apparent from the description, or may be learned by practicing one or more of the presented embodiments of the present disclosure.

According to one or more embodiments of the present disclosure, a display device includes: a substrate; a first transistor including: a first semiconductor layer on the substrate; and a first gate electrode on the first semiconductor layer, and at least partially overlapping with the first semiconductor layer; a second transistor including: a second semiconductor layer on the first gate electrode; and a second gate electrode on the second semiconductor layer, and at least partially overlapping with the second semiconductor layer; an insulating structure between the first gate electrode and the second gate electrode; and a first transfer pattern at a same layer as that of the second gate electrode, the first transfer pattern being electrically connected to the first gate electrode through a contact hole passing through the insulating structure, and including a first layer and a second layer on the first layer. The first layer of the first transfer pattern includes a first portion in the contact hole, and a second portion outside the contact hole. A thickness of the second portion of the first layer is in a range of about 450 Å to 800 Å.

In an embodiment, a thickness of the first portion of the first layer may be in a range of about 200 Å to about 500 Å.

In an embodiment, a taper angle of the insulating structure may be in a range of about 40° to about 75°.

1 In an embodiment, a thickness of the second layer may be greater than each of a thickness of the first portion of the first layer and the thickness of the second portion of the first layer.

In an embodiment, the first layer may include titanium (Ti).

In an embodiment, the display device may further include a second transfer pattern on the first transfer pattern, and electrically connecting the first transfer pattern and the second semiconductor layer to each other.

In an embodiment, the display device may further include a capacitor electrode between the first gate electrode and the first transfer pattern, and having an opening that overlaps with a portion of the first transfer pattern. The contact hole may overlap with the opening in the capacitor electrode.

In an embodiment, the insulating structure may include: a first insulating layer between the first gate electrode and the capacitor electrode; a second insulating layer between the capacitor electrode and the second semiconductor layer; and a third insulating layer between the second semiconductor layer and the first transfer pattern.

In an embodiment, the substrate may include a display area, and a peripheral area outside the display area. The display device may further include a data transfer line bypassing a partial area on the display area, and configured to receive a data signal.

In an embodiment, the data transfer line may include: a first connection line on the second gate electrode, and extending in a first direction; and a second connection line on the first connection line, and extending in a second direction crossing the first direction. The first connection line and the second connection line may be electrically connected to each other through a connection contact hole.

In an embodiment, the first connection line and the second connection line may be configured to receive a same data signal as each other.

In an embodiment, the display device may further include: a first input line, a second input line, and a third input line sequentially located in the peripheral area in a direction from an edge of the peripheral area toward a center of the peripheral area; a first data line connected to the first input line; a third data line on one side of the first data line, and connected to the third input line; and a second data line on another side of the first data line, and electrically connected to the second input line through the first connection line and the second connection line.

In an embodiment, the first connection line may be electrically insulated from the first data line, and may overlap with the first data line in at least a partial area.

In an embodiment, the first data line, the second data line, and the third data line may be located at a same layer as that of the second connection line.

In an embodiment, the first semiconductor layer may include a silicon semiconductor material.

In an embodiment, the second semiconductor layer may include an oxide semiconductor material.

According to one or more embodiments of the present disclosure, a display device includes: a substrate; a first transistor including: a first semiconductor layer on the substrate; and a first gate electrode on the first semiconductor layer, and at least partially overlapping with the first semiconductor layer; a second transistor including: a second semiconductor layer on the first gate electrode; and a second gate electrode on the second semiconductor layer, and at least partially overlapping with the second semiconductor layer; an insulating structure between the first gate electrode and the second gate electrode; and a first transfer pattern at a same layer as that of the second gate electrode, and electrically connected to the first gate electrode through a contact hole passing through the insulating structure. A taper angle of the insulating structure is in a range of about 40° to about 75°.

1 In an embodiment, the display device may further include a second transfer pattern on the first transfer pattern, and electrically connecting the first transfer pattern and the second semiconductor layer to each other.

In an embodiment, the display device may further include a capacitor electrode between the first gate electrode and the first transfer pattern, and having an opening that overlaps with a portion of the first transfer pattern. The contact hole may overlap with the opening in the capacitor electrode.

In an embodiment, the insulating structure may include: a first insulating layer between the first gate electrode and the capacitor electrode; a second insulating layer between the capacitor electrode and the second semiconductor layer; and a third insulating layer between the second semiconductor layer and the second gate electrode.

In an embodiment, the first transfer pattern may include a first layer, and a second layer on the first layer. The first layer may include a first portion in the contact hole, and a second portion outside the contact hole. A thickness of the first portion of the first layer may be in a range of about 200 Å to about 500 Å.

In an embodiment, a thickness of the second layer may be greater than each of the thickness of the first portion of the first layer and a thickness of the second portion of the first layer.

In an embodiment, the first layer may include titanium (Ti).

In an embodiment, the substrate may include a display area, and a peripheral area outside the display area. The display device may further include a data transfer line bypassing a partial area on the display area, and configured to receive a data signal.

According to one or more embodiments of the present disclosure, a method of manufacturing a display device, includes: forming a first transistor including: a first semiconductor layer disposed on a substrate; and a first gate electrode disposed on the first semiconductor layer to overlap with at least a portion of the first semiconductor layer; forming a first insulating layer on the first gate electrode; forming a capacitor electrode on the first insulating layer; forming a second insulating layer on the capacitor electrode; forming a second semiconductor layer on the second insulating layer; forming a third insulating layer on the second semiconductor layer; forming a contact hole to overlap with the first gate electrode by removing a portion of each of the first insulating layer, the second insulating layer, and the third insulating layer, and then performing a first heat treatment; and forming, on the third insulating layer, a first transfer pattern that is electrically connected to the first gate electrode through the contact hole.

In an embodiment, in the forming of the contact hole, a portion of each of the first insulating layer, the second insulating layer, and the third insulating layer may be removed so that an insulating structure including the first insulating layer, the second insulating layer, and the third insulating layer and having a taper angle in a range of about 40° to about 75° may be formed.

In an embodiment, the first transfer pattern may include a first layer, and a second layer on the first layer; the first layer may include a first portion outside the contact hole, and a second portion in the contact hole; and a thickness of the first portion of the first layer may be in a range of about 200 Å to about 500 Å.

In an embodiment, a thickness of the second portion of the first layer may be in a range of about 450 Å to about 800 Å.

In an embodiment, the method may further include performing a second heat treatment after the forming of the first transfer pattern.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view schematically illustrating a portion of a display device according to an embodiment;

FIG. 2 is a side view schematically illustrating the display device of FIG. 1;

FIG. 3 is a plan view schematically illustrating a display panel according to an embodiment;

FIGS. 4 and 5 are enlarged plan views schematically illustrating the region A of FIG. 3;

FIG. 6 is an equivalent circuit diagram of a pixel included in a display device, according to an embodiment;

FIG. 7 is a plan view schematically illustrating a structure of a pixel circuit according to an embodiment;

FIGS. 8-16 are plan views illustrating layers of elements included in the pixel circuit of FIG. 7;

FIG. 17 is a cross-sectional view schematically illustrating a portion of a structure of a pixel circuit according to an embodiment;

FIG. 18 is an enlarged plan view schematically illustrating some layers in the region B of FIG. 7;

FIG. 19 is a cross-sectional view schematically illustrating a cross-section taken along the line I-I′ of FIG. 18; and

FIGS. 20-24 are cross-sectional views illustrating a method of manufacturing a display device, according to an embodiment.

### 1 DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

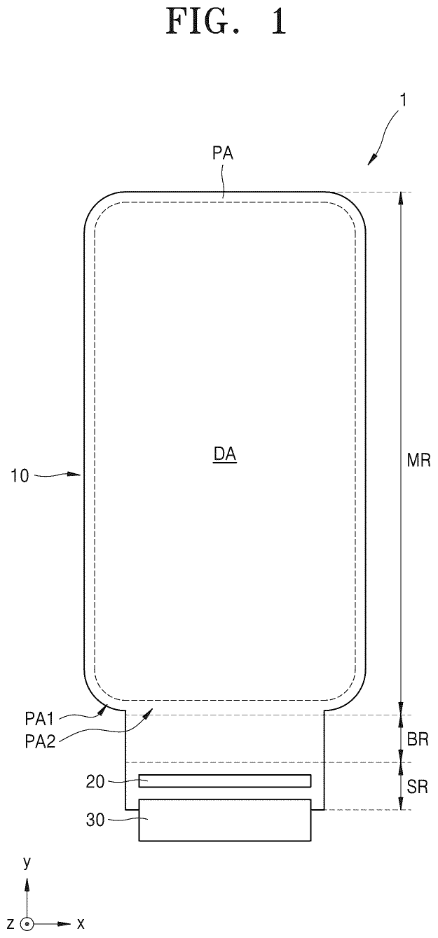

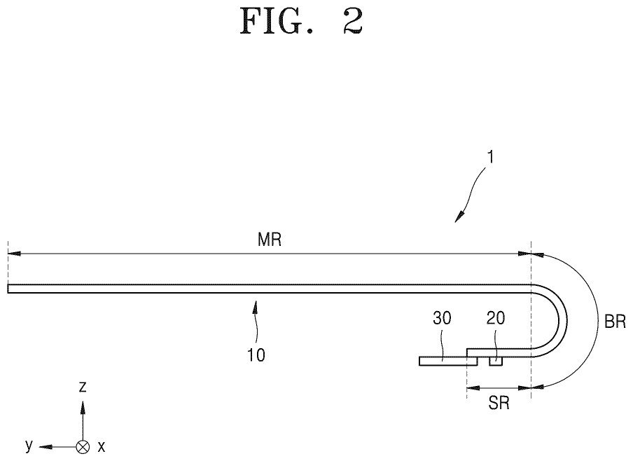

FIG. 1 is a plan view schematically illustrating a portion of a display device 1 according to an embodiment, and FIG. 2 is a side view schematically illustrating the display device 1 of FIG. 1. In FIG. 2, the display device 1 according to the present embodiment is partially bent. However, FIG. 1 shows the display device 1 that is not bent, for convenience of illustration.

Referring to FIGS. 1 and 2, the display device 1 may include a display panel 10. The display device 1 may be any suitable display device that includes the display panel 10. For example, the display device 1 may include various suitable products, such as smartphones, tablets, laptops, televisions, or billboards.

The display panel 10 may include a display area DA, and a peripheral area PA that is outside the display area DA. The display area DA is a portion in which an image is displayed, and a plurality of pixels may be arranged in the display area DA. The display area DA may have various suitable shapes, such as a circle, an ellipse, a polygon, or a specific shape. In FIG. 1, the display area DA has a rectangular shape with rounded edges.

The peripheral area PA may be arranged outside the display area DA. The peripheral area PA may include a first peripheral area PA1 arranged to surround (e.g., around a periphery of) at least part of the display area DA, and a second peripheral area PA2 extending to one side (e.g., in a −y direction) of the display area DA. A width of the second peripheral area PA2 in one direction (e.g., an x-axis direction) may be less than a width of the display area DA. As such, bending of at least a portion of the second peripheral area PA2 may be facilitated.

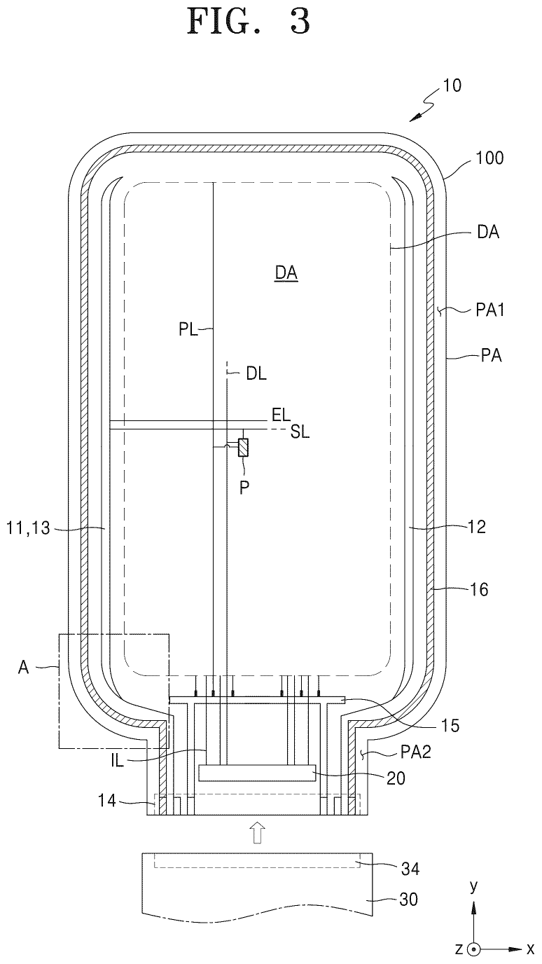

In addition, because the display panel 10 includes a substrate 100 (e.g., see FIG. 3), it may be understood that the substrate 100 includes the display area DA and the peripheral area PA. Hereinbelow, the substrate 100 is described in more detail as including the display area DA and the peripheral area PA, for convenience of illustration.

The display panel 10 may include a main area MR, a bending area BR that is outside the main area MR, and a sub-area SR that is spaced apart from the main area MR with the bending area BR therebetween. In other words, the main area MR may be arranged on one side of the bending area BR, and the sub-area SR may be arranged on the other side (e.g., the opposite side) of the bending area BR. Because the display panel 10 is bent in the bending area BR, as shown in FIG. 2, when viewed from the z-axis direction (e.g., in a plan view), at least a portion of the sub-area SR may overlap with the main area MR. However, the present disclosure is not limited to display devices that are bent, and one or more embodiments may be applied to display devices that are unbendable. The sub-area SR may be a video display area, as described in more detail below. By allowing the display panel 10 to be bent in the bending area BR, when the display device is viewed from the front (e.g., in the z direction), a non-display area may not be visible, or even though the non-display is visible, the visible area may be minimized or reduced.

A data pad unit (e.g., a data pad area) 20 may be arranged in the sub-area SR of the display panel 10. The data pad unit 20 may include an integrated circuit (e.g., a driving chip) to drive the display panel 10. The integrated circuit may be a data driving integrated circuit to generate data signals, but the present disclosure is not limited thereto.

The data pad unit 20 may be mounted in the sub-area SR of the display panel 10. Although the data pad unit 20 is mounted on the same surface as that of a display surface of the display area DA, when the data pad unit 20 is bent in the bending area BR, as described above, the data pad unit 20 may be positioned on a rear surface of the main area MR. The data pad unit 20 may include a plurality of pads.

A printed circuit board 30 or the like may be attached to an end of the sub-area SR of the display panel 10. The printed circuit board 30 or the like may be electrically connected to the data pad unit 20 or the like through the pads.

Hereinbelow, an organic light-emitting display device is described in more detail as a representative example of the display device 1 according to an embodiment, but the present disclosure is not limited thereto. In another embodiment, the display device 1 of one or more embodiments may be an inorganic light-emitting display (e.g., inorganic electroluminescent display device) or a quantum dot light-emitting display. For example, an emission layer of a display element provided in the display device 1 may include an organic material, an inorganic material, quantum dots, both an organic material and quantum dots, or both an inorganic material and quantum dots.

FIG. 3 is a plan view schematically illustrating the display panel 10 according to an embodiment.

Referring to FIG. 3, the display panel 10 may include the substrate 100. Various elements included in the display panel 10 may be disposed on the substrate 100.

The substrate 100 may include glass, metal, or a polymer resin. When the display panel 10 is bent in the bending area BR, as described above, the substrate 100 may have flexible or bendable properties. In this case, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers, each including at least one of the polymer resins described above, and a barrier layer including an inorganic material (e.g., silicon oxide, silicon nitride, silicon oxynitride, or the like), and various suitable modifications may be made.

A plurality of pixels P may be arranged in the display area DA. Each of the pixels P denotes a sub-pixel, and may be implemented by a display element such as an organic light-emitting diode OLED. The pixel P may emit, for example, red, green, blue, or white light.

The pixel P may be electrically connected to outer circuits arranged in the peripheral area PA. A first scan driving circuit 11, a second scan driving circuit 12, an emission control driving circuit 13, a terminal 14, a first power supply line 15, and a second power supply line 16 may be arranged in the peripheral area PA.

The first scan driving circuit 11 may provide a scan signal to the pixel P through a scan line SL. The second scan driving circuit 12 may be arranged in parallel with the first scan driving circuit 11 with the display area DA therebetween. Some of the pixels P arranged in the display area DA may be electrically connected to the first scan driving circuit 11, and others of the pixels may be connected to the second scan driving circuit 12. In another embodiment, the second scan driving circuit 12 may be omitted as needed or desired.

The emission control driving circuit 13 may be arranged on a side of the first scan driving circuit 11, and may provide an emission control signal to the pixel P through an emission control line EL. In FIG. 3, the emission control driving circuit 13 is illustrated as being arranged on one side of the display area DA. However, the emission control driving circuit 13 may be arranged on opposite sides of the display area DA.

The terminal 14 may be arranged in the second peripheral area PA2 of the substrate 100. The terminal 14 may be exposed without being covered by an insulating layer, and may be electrically connected to the printed circuit board 30. A terminal 34 of the printed circuit board 30 may be electrically connected to the terminal 14 of the display panel 10.

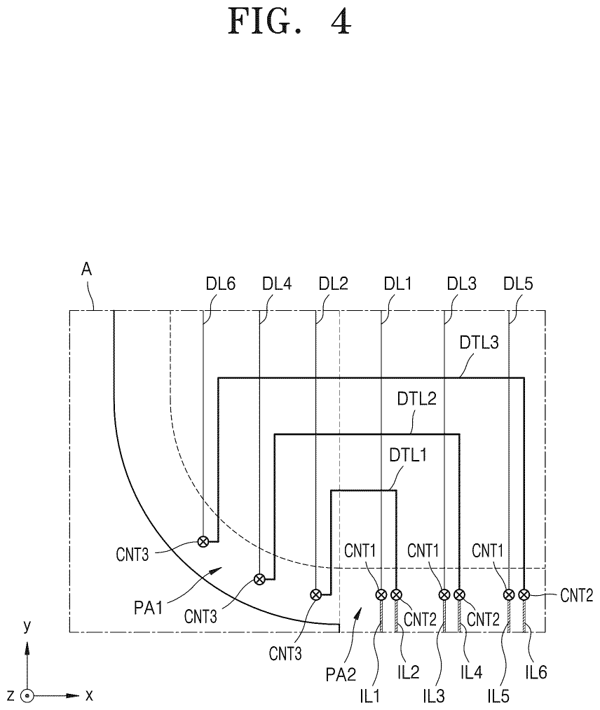

The printed circuit board 30 may transmit a signal or power of a control unit (e.g., a controller) to the display panel 10. Control signals generated by the control unit may be transmitted to driving circuits 11, 12, and 13, respectively, through the printed circuit board 30. In addition, the control unit may provide first and second power voltages ELVDD and ELVSS (e.g., see FIG. 4) to first and second power supply lines 15 and 16, respectively. The first power voltage (e.g., a driving voltage) ELVDD may be provided to each pixel P through a driving voltage line PL that is connected to the first power supply line 15, and the second power voltage (e.g., a common voltage) ELVSS may be provided to an opposite electrode of the pixel P connected to the second power supply line 16. The first power supply line 15 may be provided to extend in one direction (e.g., an x direction) from a lower side of the second peripheral area PA2. The second power supply line 16 may have a loop shape having one open side, and may partially surround (e.g., around a periphery of) the display area DA.

In addition, the control unit may generate a data signal, and the generated data signal may be transmitted to an input line IL through the data pad unit 20 to be transmitted to the pixel P through a data line DL connected to the input line IL.

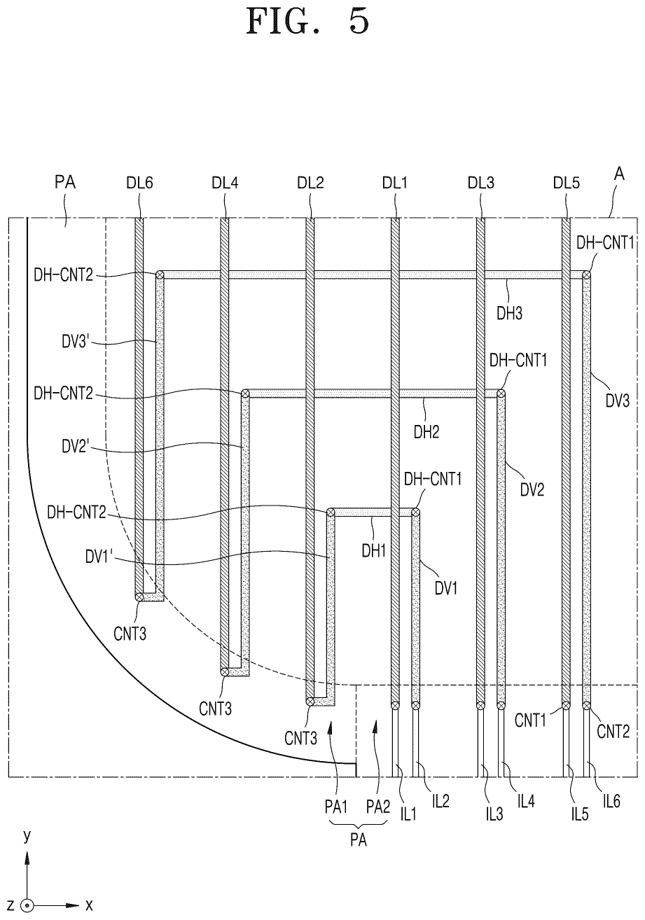

FIGS. 4 and 5 are enlarged plan views schematically illustrating the region A of FIG. 3.

Referring to FIG. 4, various signals may be transmitted to the display area DA. For example, a data signal or the like for adjusting a brightness of each pixel may be transmitted to the display area DA, and thus, as shown in FIG. 4, data lines DL1 to DL6 that are parallel or approximately parallel to each other may be positioned on the substrate in the display area DA. In addition to the data lines DL1 to DL6, various lines, such as a power line or a scan line, may be positioned inside or outside the display area DA.

In the peripheral area PA, or in other words, the second peripheral area PA2, first to sixth input lines IL1 to IL6 may be arranged, which are connected to the data pad unit 20 and receive data signals. The first to sixth data lines DL1 to DL6 may be connected to the first to sixth input lines IL1 to IL6, respectively, to transmit a data signal to corresponding pixels.

In FIGS. 4 and 5, six input lines and six data lines are shown for convenience of illustration. However, the number of input lines and the number of data lines may more or substantially more than 6.

The first to sixth input lines IL1 to IL6 may be sequentially arranged along a direction to the center of the second peripheral area PA2 from an edge of the second peripheral area PA2. In an embodiment, the first, third, and fifth input lines IL1, IL3, and IL5 are odd-numbered and may be respectively connected to the first, third, and fifth data lines DL1, DL3, and DL5 that are continuously arranged adjacent to each other. The first, third, and fifth input lines IL1, IL3, and IL5 may be integrally formed with the first, third, and fifth data lines DL1, DL3, and DL5, or may be connected to a first contact hole CNT1, as shown in FIG. 4. The first, third, and fifth data lines DL1, DL3, and DL5 may receive data signals from the first, third, and fifth input lines IL1, IL3, and IL5, respectively.

The second, fourth, and sixth input lines IL2, IL4, and IL6 may be respectively connected through first to third data transfer lines DTL1 to DTL3 to the second, fourth, and sixth data lines DL2, DL4, and DL6, which are continuously arranged adjacent to each other. In other words, the second, fourth, and sixth data lines DL2, DL4, and DL6 may respectively receive data signals from the second, fourth, and sixth input lines IL2, IL4, and IL6 via the first to third data transfer lines DTL1 to DTL3.

The first to third data transfer lines DTL1 to DTL3 may be arranged to pass through the display area DA by bypassing a portion of the display area DA adjacent to the peripheral area PA. The second input line IL2 may be electrically connected to the second data line DL2 through the first data transfer line DTL1. The fourth input line IL4 may be electrically connected to the fourth data line DL4 through the second data transfer line DTL2. The sixth input line IL6 may be electrically connected to the sixth data line DL6 through the third data transfer line DTL3.

One end of each of the first to third data transfer lines DTL1 to DTL3 may be connected to the second, fourth, and sixth input lines IL2, IL4, and IL6 through a second contact hole CNT2, and the other end of each of the first to third data transfer lines DTL1 to DTL3 may be connected to the second, fourth, and sixth data lines DL2, DL4, and DL6 through a third contact hole CNT3. In FIGS. 4 and 5, the second contact hole CNT2 and the third contact hole CNT3 are shown as positioned in the peripheral area PA. However, the present disclosure is not limited thereto. In another embodiment, the second contact hole CNT2 and/or the third contact hole CNT3 may be positioned in the display area DA. As such, the second input line IL2 may transmit a data signal to the second input line IL2, the fourth input line IL4 may transmit a data signal to the fourth data line DL4, and the sixth input line IL6 may be transmit a data signal to the sixth data line DL6.

Referring to FIG. 5, a connection relationship outside the display area DA in which the first to third data transfer lines DTL1 to DTL3 are arranged is shown. FIG. 5 may be understood as a concrete illustration of FIG. 4 described above.

Referring to FIG. 5, the second, fourth, and sixth input lines IL2, IL4, and IL6 may be electrically connected to the second, fourth, and sixth data lines DL2, DL4, and DL6, respectively, through the first to third data transfer lines DTL1 to DTL3.

In an embodiment, the first to third data transfer lines DTL1 to DTL3 include first connection lines DH1 to DH3, second connection lines DV1 to DV3, and third connection lines DV1′ to DV3′, respectively. The first connection lines DH1 to DH3 may extend in a first direction (e.g., an x direction) crossing a second direction (e.g., a y direction). The second connection lines DV1 to DV3 and the third connection lines DV1′ to DV3′ may extend in the second direction (e.g., the y direction) that is parallel to or approximately parallel to the data line.

The second, fourth, and sixth input lines IL2, IL4, and IL6 may be connected to the second connection lines DV1 to DV3, respectively, through the second contact hole CNT2. The third connection lines DV1′ to DV3′ may be connected to the second, fourth, and sixth data lines DL2, DL4, and DL6, respectively, through the third contact hole CNT3. The first connection lines DH1 to DH3 may be connected to the second connection lines DV1 to DV3 and the third connection lines DV1′ to DV3′ through a first connection contact hole DH-CNT1 and a second connection contact hole DH-CNT2, which are respectively positioned at one end and the other end (e.g., an opposite end) of each of the first connection lines DH1 to DH3.

In an embodiment, the first connection lines DH1 to DH3, the second connection lines DV1 to DV3, and the third connection lines DV1′ to DV3′ may be arranged at (e.g., in or on) the same layer as each other, or at least some of the first connection lines DH1 to DH3, the second connection lines DV1 to DV3, and/or the third connection lines DV1′ to DV3′ may be disposed at (e.g., in or on) different layers from each other. For example, the second connection lines DV1 to DV3 and the third connection lines DV1′ to DV3′ may be arranged at (e.g., in or on) the same layer as each other, and the first connection lines DH1 to DH3 may be disposed at (e.g., in or on) a layer different from the layer of the second connection lines DV1 to DV3 and the third connection lines DV1′ to DV3′. As used herein, when the lines are referred to as being arranged at (e.g., in or on) the same layer as each other, the lines may be concurrently or substantially simultaneously formed with each other through the same mask process, and may include the same material as each other. As described above, when the second connection lines DV1 to DV3 and the third connection lines DV1′ to DV3′ are arranged at (e.g., in or on) the same layer as each other, the second connection lines DV1 to DV3 and the third connection lines DV1′ to DV3′ may be arranged at (e.g., in or on) the same layer as that of which the data line DL is arranged.

The first connection lines DH1 to DH3 may overlap with some of the first to sixth data lines DL1 to DL6. The first connection lines DH1 to DH3 may be arranged to pass under the first to sixth data lines DL1 to DL6. For example, as shown in FIG. 5, a 2-1 connection line DH1 may partially overlap with the first data line DL1, a 2-2 connection line DH2 may partially overlap with the first, second, and third data lines DL1, DL2, and DL3, and a 2-3 connection line DH3 may partially overlap with the first, second, third, fourth, and fifth data lines DL1, DL2, DL3, DL4, and DL5. The first connection lines DH1 to DH3 may not be electrically connected to the first to sixth data lines DL1 to DL6.

In some embodiments, a dummy line may be further arranged at the same layer as that of which the first connection lines DH1 to DH3, the second connection lines DV1 to DV3, and the third connection lines DV1′ to DV3′ are arranged. The dummy line may be continuously formed with each of the first connection lines DH1 to DH3, the second connection lines DV1 to DV3, and the third connection lines DV1′ to DV3′, and may be provided to be electrically disconnected in some areas to constitute the first to third data transfer lines DTL1 to DTL3. The disconnected portion may be positioned around the first connection contact hole DH-CNT1 and the second connection contact hole DH-CNT2 described above. The dummy line may be present in the form of a floating electrode isolated from other electrodes and/or lines, and a signal or a constant voltage may be applied to prevent or substantially prevent static electricity.

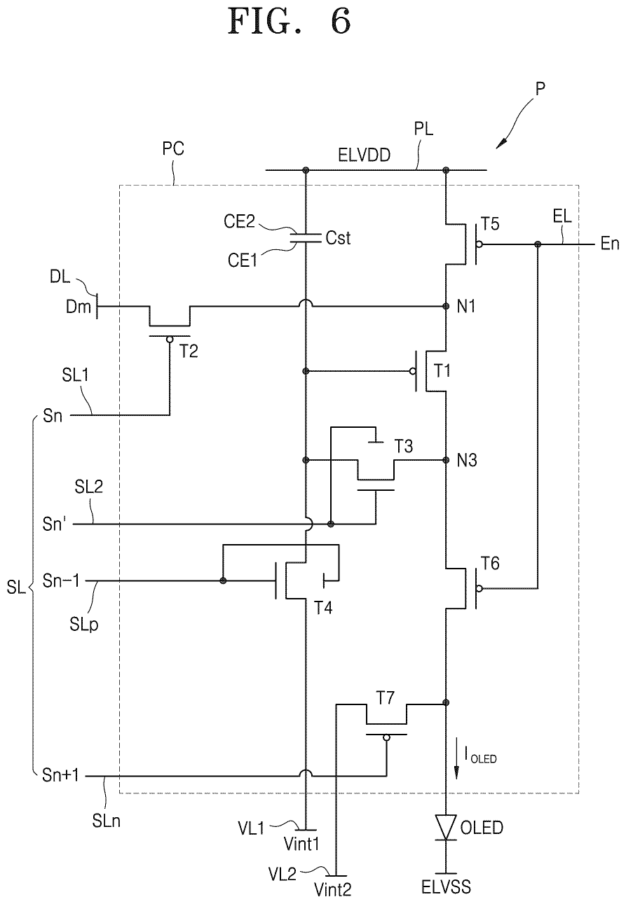

FIG. 6 is an equivalent circuit diagram of a pixel P included in a display device, according to an embodiment.

Referring to FIG. 6, the pixel P may include a pixel circuit PC and an organic light-emitting diode OLED.

For example, as shown in FIG. 6, the pixel circuit PC may include a plurality of thin-film transistors T1 to T7 and a storage capacitor Cst. The plurality of thin-film transistors T1 to T7 and the storage capacitor Cst may be connected to signal lines SL1, SL2, SLp, SLn, EL, and DL, a first initialization voltage line VL1, a second initialization voltage line VL2 (e.g., an anode initialization voltage line), and a driving voltage line PL. In an embodiment, at least one of the lines described above, for example, such as the driving voltage line PL, may be shared by pixels P that are adjacent to each other.

The plurality of thin-film transistors T1 to T7 may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7. The driving thin-film transistor T1, the switching thin-film transistor T2, the compensation thin-film transistor T3, the first initialization thin-film transistor T4, the operation control thin-film transistor T5, the emission control thin-film transistor T6, and the second initialization thin-film transistor T7 may be referred to as first to seventh transistors, respectively.

The organic light-emitting diode OLED may include a first electrode (e.g., an anode electrode) and a second electrode (e.g., a cathode electrode). The first electrode of the organic light-emitting diode OLED be connected to the driving thin-film transistor T1 via the emission control thin-film transistor T6 to receive a driving current. The second electrode may receive a low-power voltage ELVSS. The organic light-emitting diode OLED may generate light having a luminance corresponding to the driving current.

Some of the plurality of thin-film transistors T1 to T7 may be provided as n-channel metal-oxide-semiconductor field-effect transistors (MOSFETs; NMOSs), and others may be provided as p-channel MOSFETs (PMOSs). For example, the compensation thin-film transistor T3 and the first initialization thin-film transistor T4 from among the plurality of thin-film transistors T1 to T7 may be provided as NMOSs, and the others may be provided as PMOSs.

In another embodiment, the compensation thin-film transistor T3, the first initialization thin-film transistor T4, and the second initialization thin-film transistor T7 from among the plurality of thin-film transistors T1 to T7 may be provided as NMOSs, and the others may be provided as PMOSs. In some embodiments, only one of the plurality of thin-film transistors T1 to T7 may be provided as NMOSs, and the others may be provided as PMOSs. In some embodiments, the plurality of thin-film transistors T1 to T7 may all be provided as NMOSs.

The signal lines may include a first scan line SL1 to transmit a first scan signal Sn, a second scan line SL2 to transmit a second scan signal SN″, a previous scan line SLp to transmit a previous scan signal Sn-1 to the first initialization thin-film transistor T4, the emission control line EL to transmit an emission control signal En to the operation control thin-film transistor T5 and the emission control thin-film transistor T6, a next scan line SLn to transmit a next scan signal Sn+1 to the second initialization thin-film transistor T7, and the data line DL crossing the first scan line SL1 and to transmit a data signal Dm.

The driving voltage line PL may transfer the driving voltage ELVDD to the driving thin-film transistor T1, and the first initialization voltage line VL1 may transmit a first initialization voltage Vint1 for initializing the driving thin-film transistor T1 and a pixel electrode.

A driving gate electrode of the driving thin-film transistor T1 may be connected to the storage capacitor Cst, a driving source region of the driving thin-film transistor T1 may be connected to the driving voltage line PL via the operation control thin-film transistor T5, and a driving drain region of the driving thin-film transistor T1 may be electrically connected to the pixel electrode of the operation control thin-film transistor T5 via the emission control thin-film transistor T6. In response to a switching operation of the switching thin-film transistor T2, the driving thin-film transistor T1 may receive the data signal Dm and supply a driving current IOLED to the organic light-emitting diode OLED.

A switching gate electrode of the switching thin-film transistor T2 may be connected to the first scan line SL1 configured to transmit the first scan signal Sn, a switching source region of the switching thin-film transistor T2 may be connected to the data line DL, and a switching drain region of the switching thin-film transistor T2 may be connected to the driving voltage line PL via the operation control thin-film transistor T5 and to the driving source region of the driving thin-film transistor T1. The switching thin-film transistor T2 may be turned on in response to the first scan signal Sn received via the first scan line SL1, and may perform a switching operation for transferring the data signal Dm received via the data line DL to the driving source region of the driving thin-film transistor T1.

A compensation gate electrode of the compensation thin-film transistor T3 may be connected to the second scan line SL2. A compensation drain region of the compensation thin-film transistor T3 may be connected to the pixel electrode of the organic light-emitting diode OLED via the emission control thin-film transistor T6 and to the driving drain region of the driving thin-film transistor T1. A compensation source region of the compensation thin-film transistor T3 may be connected to a first electrode CE1 of the storage capacitor Cst and the driving gate electrode of the driving thin-film transistor T1. In addition, the compensation source region may be connected to a first initialization drain region of the first initialization thin-film transistor T4.

The compensation thin-film transistor T3 may be turned on in response to a second scan signal Sn′ received via the second scan line SL2, and may electrically connect the driving gate electrode to the driving drain region of the driving thin-film transistor T1 to diode-connect the driving thin-film transistor T1.

A first initialization gate electrode of the first initialization thin-film transistor T4 may be connected to the previous scan line SLp. A first initialization source region of the first initialization thin-film transistor T4 may be connected to a second initialization source region of the second initialization thin-film transistor T7 and the first initialization voltage line VL1. The first initialization drain region of the first initialization thin-film transistor T4 may be connected to the first electrode CE1 of the storage capacitor Cst, the compensation source region of the compensation thin-film transistor T3, and the driving gate electrode of the driving thin-film transistor T1. The first initialization thin-film transistor T4 may be turned on in response to the previous scan signal Sn-1 received via the previous scan line SLp, and may perform an initialization operation for transferring the first initialization voltage Vint1 to the driving gate electrode of the driving thin-film transistor T1 and initializing a voltage of the driving gate electrode of the driving thin-film transistor T1.

An operation control gate electrode of the operation control thin-film transistor T5 may be connected to the emission control line EL, an operation control source region of the operation control thin-film transistor T5 may be connected to the driving voltage line PL, and an operation control drain region of the operation control thin-film transistor T5 may be connected to the driving source region of the driving thin-film transistor T1 and the switching drain region of the switching thin-film transistor T2.

An emission control gate electrode of the emission control thin-film transistor T6 may be connected to the emission control line EL, an emission control source region of the emission control thin-film transistor T6 may be connected to the driving drain region of the driving thin-film transistor T1 and the compensation drain region of the compensation thin-film transistor T3, and an emission control drain region of the emission control thin-film transistor T6 may be electrically connected to a second initialization drain region of the second initialization thin-film transistor T7 and the pixel electrode of the organic light-emitting diode OLED.

The operation control thin-film transistor T5 and the emission control thin-film transistor T6 may be concurrently or substantially simultaneously turned on with each other in response to the emission control signal En received via the emission control line EL, so that the driving voltage ELVDD is transmitted to the organic light-emitting diode OLED to cause the driving current IOLED to flow to the organic light-emitting diode OLED.

A second initialization gate electrode of the second initialization thin-film transistor T7 may be connected to the next scan line SLn, the second initialization drain region of the second initialization thin-film transistor T7 may be connected to the emission control drain region of the emission control thin-film transistor T6 and the pixel electrode of the organic light-emitting diode OLED, and a second initialization source region of the second initialization thin-film transistor T7 may be connected to the second initialization voltage line VL2 to receive a second initialization voltage Vint2. The second initialization thin-film transistor T7 may be turned on in response to the next scan signal Sn+1 received via the next scan line SLn, and may initialize the pixel electrode of the organic light-emitting diode OLED.

As shown in FIG. 2, the second initialization thin-film transistor T7 may be connected to the next scan line SLn. In another embodiment, the second initialization thin-film transistor T7 may be connected to the emission control line EL and driven in response to the emission control signal En. However, positions of the source regions and the drain regions may be variously modified depending on the kind of transistor (e.g., p-type or n-type).

The storage capacitor Cst may include the first electrode CE1 and a second electrode CE2. The first electrode CE1 of the storage capacitor Cst may be connected to the driving gate electrode of the driving thin-film transistor T1, and the second electrode CE2 of the storage capacitor Cst may be connected to the driving voltage line PL. The storage capacitor Cst may store a charge corresponding to a voltage difference between a voltage of the driving gate electrode of the driving thin-film transistor T1 and the driving voltage ELVDD.

Detailed operations of each of the pixels P according to an embodiment are described hereinafter.

During an initialization period, when the previous scan signal Sn-1 is supplied through the previous scan line SLp, the first initialization thin-film transistor T4 may be turned on in response to the previous scan signal Sn-1, and the driving thin-film transistor T1 may be initialized by the first initialization voltage Vint1 supplied from the first initialization voltage line VL1.

During a data programming period, when the first scan signal Sn and a second scan signal Sn′ are supplied through the first scan line SL1 and the second scan line SL2, respectively, the switching thin-film transistor T2 and the compensation thin-film transistor T3 are turned on in response to the first scan signal Sn and the second scan signal Sn′. In this case, the driving thin-film transistor T1 may be diode-connected by the compensation thin-film transistor T3 that is turned on, and forward biased.

Then, a compensation voltage (Dm+Vth, where Vth is a negative value), which is obtained by subtracting the data signal Dm supplied from the data line DL by a threshold voltage (Vth) of the driving thin-film transistor T1, may be applied to the driving gate electrode.

The driving voltage ELVDD and the compensation voltage (Dm+Vth) may be applied to both terminals of the storage capacitor Cst, and the storage capacitor Cst stores a charge corresponding to a voltage difference between the terminals.

During an emission period, the operation control thin-film transistor T5 and the emission control thin-film transistor T6 may be turned on according to the emission control signal En supplied from the emission control line EL. A driving current IOLED according to the voltage difference between the voltage of the driving gate electrode of the driving thin-film transistor T1 and the driving voltage ELVDD may be generated, and the driving current IOLED may be supplied to the organic light-emitting diode OLED through the emission control thin-film transistor T6.

In the present embodiment, at least one of the plurality of thin-film transistors T1 to T7 may include a semiconductor layer containing an oxide, and the other ones may include a semiconductor layer containing silicon.

For example, the driving thin-film transistor T1, which directly affects the brightness of the display device, may include a semiconductor layer containing polycrystalline silicon with high reliability, so that a high-resolution display device may be implemented.

Because an oxide semiconductor has high carrier mobility and low leakage current, a voltage drop may not be significant even when the display device is driven for a long time. In other words, even during low-frequency driving, a color change of an image due to a voltage drop may not be significant, and thus, the display device may be driven at a low frequency.

As described above, because an oxide semiconductor has low leakage current, at least one of the compensation thin-film transistor T3, the first initialization thin-film transistor T4, and/or the second initialization thin-film transistor T7 connected to the driving gate electrode of the driving thin-film transistor T1 may be adopted as an oxide semiconductor to reduce power consumption while preventing or substantially preventing a leakage current that may flow to the driving gate electrode.

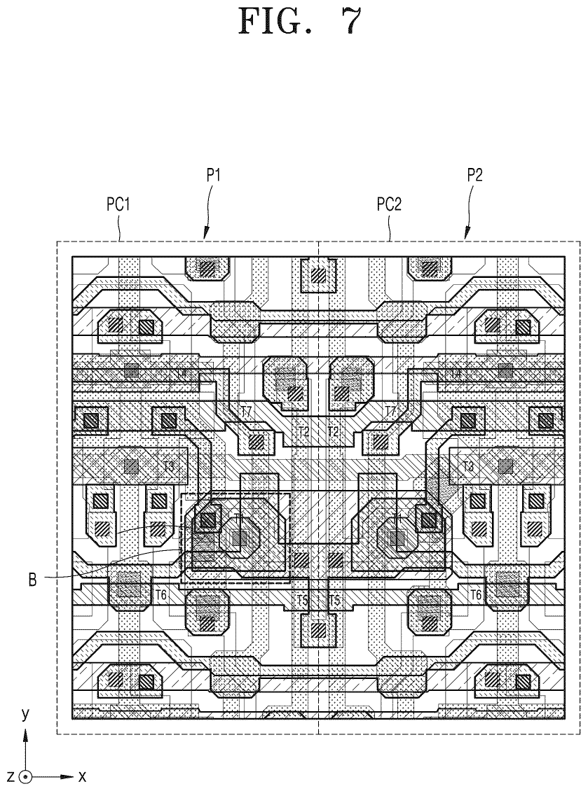

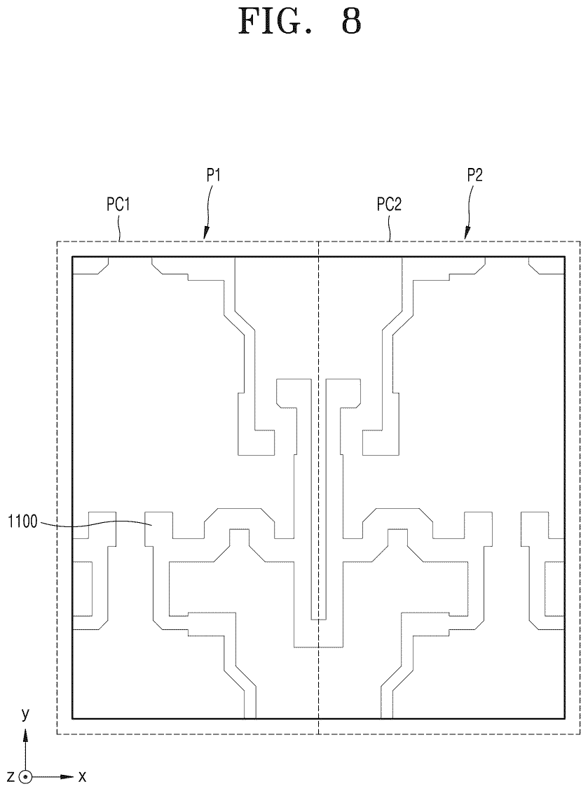

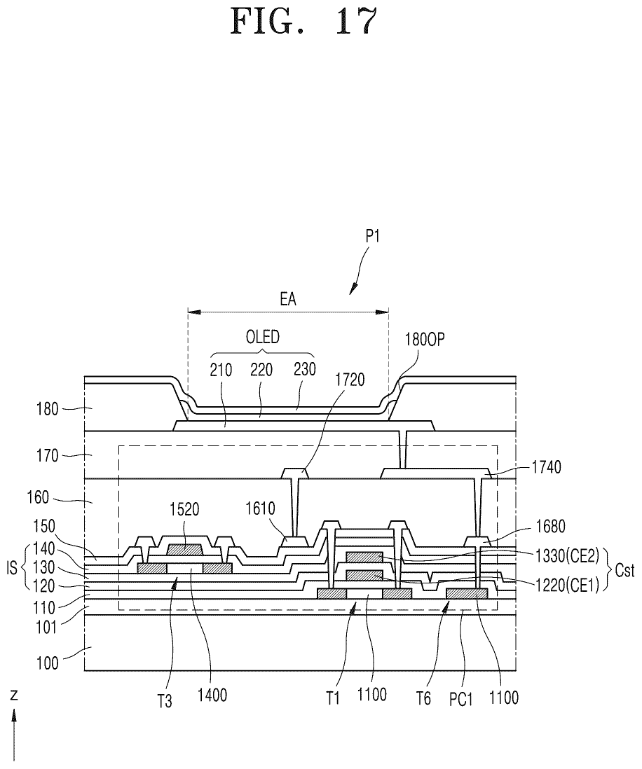

FIG. 7 is a plan view schematically illustrating a structure of a pixel circuit according to an embodiment. FIGS. 8 through 16 are plan views illustrating layers of elements included in the pixel circuit of FIG. 7. FIG. 17 is a cross-sectional view schematically illustrating a portion of a structure of a pixel circuit according to an embodiment.

FIG. 8 shows a first semiconductor layer 1100.

Referring to FIG. 8 together with FIGS. 7 and 17, the display device 1 may include a first pixel P1 and a second pixel P2 that are adjacent to each other. In an embodiment, as shown in FIGS. 7 and 8, the first pixel P1 and the second pixel P2 may have a structure in which the first pixel P1 and the second pixel P2 are symmetrical or substantially symmetrical to each other with respect to an imaginary line. In another embodiment, the first pixel P1 and the second pixel P2 may have a structure in which the same or substantially the same pixel structure is continuously repeated rather than a symmetrical structure. The first pixel P1 may include a first pixel circuit PC1, and the second pixel P2 may include a second pixel circuit PC2.

Hereinbelow, for convenience, the elements are described in more detail based on the first pixel circuit PC1. However, the elements may also be symmetrically or substantially symmetrically provided in the second pixel circuit PC2.

The substrate 100 may include glass, quartz, plastic, or the like. In an embodiment, the substrate 100 may include plastic, and thus, the display device 1 may have flexible properties. In this case, the substrate 100 may have a structure in which at least one organic film layer and at least one barrier layer are alternately stacked with each other. For example, the organic film layer may be formed by using an organic material such as polyimide, and the barrier layer may be formed by using an inorganic material.

A buffer layer 101 (e.g., see FIG. 17) may be disposed on the substrate 100. The buffer layer 101 may prevent or substantially prevent metal atoms or impurities from diffusing from the substrate 100 into the first semiconductor layer 1100. In addition, the buffer layer 101 may adjust a speed at which heat is provided during a crystallization process for forming the first semiconductor layer 1100, so that the first semiconductor layer 1100 may be uniformly or substantially uniformly formed.

The first semiconductor layer 1100 may be disposed on the buffer layer 101. A portion of the first semiconductor layer 1100 may be included in the first pixel circuit PC1, and another portion of the first semiconductor layer 1100 may be included in the second pixel circuit PC2. A portion of the first semiconductor layer 1100 corresponding to the first pixel circuit PC1 and a portion of the first semiconductor layer 1100 corresponding to the second pixel circuit PC2 may be symmetrical or substantially symmetrical to each other with respect to an imaginary line.

In an embodiment, the first semiconductor layer 1100 may include a silicon semiconductor. For example, the silicon semiconductor may include amorphous silicon, polycrystalline silicon, or the like. For example, the first semiconductor layer 1100 may include low-temperature polysilicon (LTPS).

In an embodiment, ions may be injected into the first semiconductor layer 1100. For example, when the driving thin-film transistor T1, the switching thin-film transistor T2, the operation control thin-film transistor T5, the emission control thin-film transistor T6, and the second initialization thin-film transistor T7 are PMOS transistors, ions such as boron may be injected into the first semiconductor layer 1100.

A first gate insulating layer 110 (e.g., see FIG. 17) may cover the first semiconductor layer 1100, and may be disposed on the buffer layer 101. The first gate insulating layer 110 may be arranged between the first semiconductor layer 1100 and a first conductive layer 1200 described in more detail below. The first gate insulating layer 110 may contain an insulating material. For example, the first gate insulating layer 110 may contain silicon oxide, silicon nitride, silicon oxynitride, aluminum oxide, or the like.

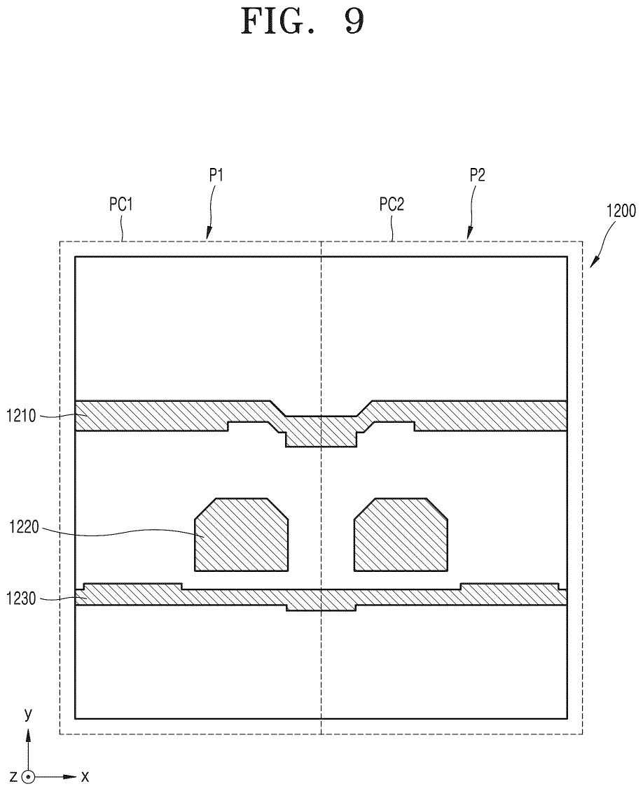

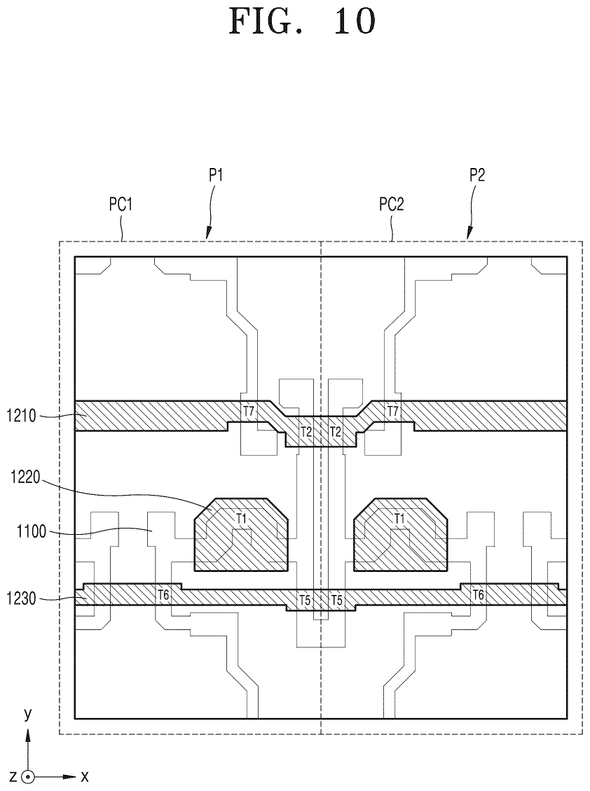

FIG. 9 shows the first conductive layer 1200. FIG. 10 shows an arrangement of the driving thin-film transistor T1, the switching thin-film transistor T2, the operation control thin-film transistor T5, the emission control thin-film transistor T6, and the second initialization thin-film transistor T7, and shows the first semiconductor layer 1100 of FIG. 8 and the first conductive layer 1200 of FIG. 9 together.

Referring to FIGS. 9 and 10 together with FIGS. 7 and 17, the first conductive layer 1200 may be disposed on the first gate insulating layer 110. The first conductive layer 1200 may be disposed on the first semiconductor layer 1100. The first conductive layer 1200 may include a first gate line 1210, a first gate electrode 1220, and a second gate line 1230.

The first gate line 1210 may extend in the first direction (e.g., the x direction). The first gate line 1210 may correspond to the first scan line SL1 (e.g., see FIG. 6). The first gate line 1210 and the first semiconductor layer 1100 may constitute the switching thin-film transistor T2. In other words, the switching thin-film transistor T2 may include the first semiconductor layer 1100, and the first gate line 1210 at least partially overlapping with the first semiconductor layer 1100. For example, the first scan signal Sn (e.g., see FIG. 6) may be provided to the first gate line 1210. In addition, the first gate line 1210 and the first semiconductor layer 1100 may constitute the second initialization thin-film transistor T7. In other words, the second initialization thin-film transistor T7 may include the first semiconductor layer 1100, and the first gate line 1210 at least partially overlapping with the first semiconductor layer 1100. For example, the next scan line Sn+1 (e.g., see FIG. 6) may be provided to the first gate line 1210. The first scan signal Sn (e.g., see FIG. 6) and the next scan signal Sn+1 may have the same or substantially the same waveform as each other with a time difference.

The first gate electrode 1220 may be arranged in an island shape. The first gate electrode 1220 and the first semiconductor layer 1100 may constitute the driving thin-film transistor T1. In other words, the driving thin-film transistor T1 may include the first semiconductor layer 1100, and the first gate electrode 1220 at least partially overlapping with the first semiconductor layer 1100.

The second gate line 1230 may extend in the first direction (e.g., the x direction). The second gate line 1230 may correspond to the emission control line EL (e.g., see FIG. 6). The second gate line 1230 and the first semiconductor layer 1100 may constitute the operation control and emission control thin-film transistors T5 and T6. In other words, each of the operation control and emission control thin-film transistors T5 and T6 may include the first semiconductor layer 1100, and the second gate line 1230 at least partially overlapping with the first semiconductor layer 1100. For example, the emission control signal En (e.g., see FIG. 6) may be provided to the second gate line 1230.

The first conductive layer 1200 may contain a metal, an alloy, a conductive metal oxide, a transparent conductive material, or the like. For example, the first conductive layer 1200 may include a silver (Ag)-containing alloy, molybdenum (Mo), a Mo-containing alloy, aluminum (Al), an Al-containing alloy, aluminum nitride (AlN), tungsten (W), tungsten nitride (WN), copper (Cu), nickel (Ni), chrome (Cr), chrome nitride (CrN), titanium (Ti), tantalum (Ta), platinum (Pt), scandium (Sc), indium tin oxide (ITO), indium zinc oxide (IZO), and/or the like.

A second gate insulating layer 120 (e.g., see FIG. 17) may cover the first conductive layer 1200, and may be disposed on the first gate insulating layer 110. The second gate insulating layer 120 may be disposed on the first gate line 1210, the first gate electrode 1220, and the second gate line 1230. The second gate insulating layer 120 may be arranged between the first conductive layer 1200 and a second conductive layer 1300 that is described in more detail below. Similar to the first gate insulating layer 110, the second gate insulating layer 120 may include an insulating material.

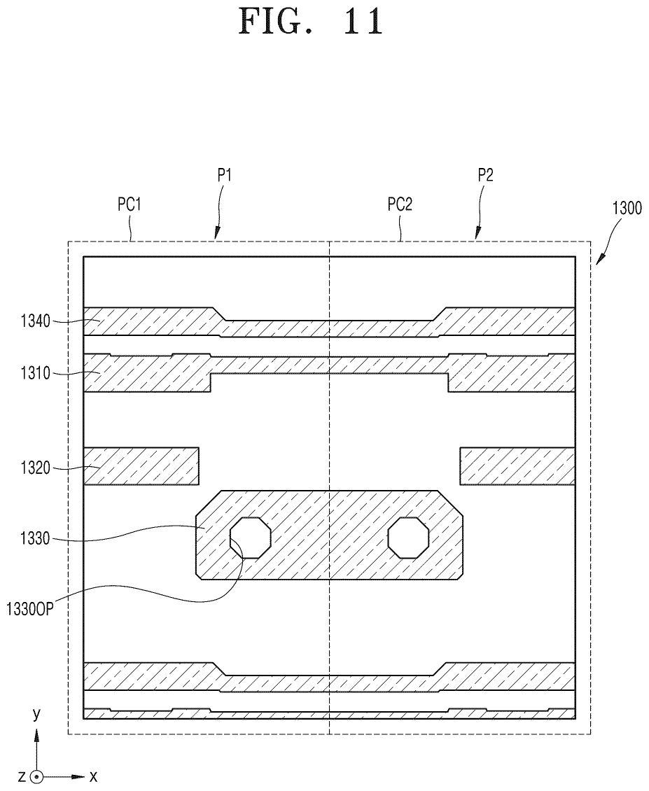

FIG. 11 shows the second conductive layer 1300.

Referring to FIG. 11 together with FIGS. 7 and 17, the second conductive layer 1300 may be disposed on the second gate insulating layer 120 (e.g., see FIG. 17). The second conductive layer 1300 may be disposed on the first conductive layer 1200. The second conductive layer 1300 may include a third gate line 1310, a fourth gate line 1320, a capacitor electrode 1330 (e.g., the second electrode CE2 of FIG. 6), and a first initialization voltage line 1340 (e.g., the first initialization voltage line VL1 of FIG. 6). In other words, the third gate line 1310, the fourth gate line 1320, the capacitor electrode 1330, and the first initialization voltage line 1340 may be arranged at (e.g., in or on) the same layer as each other.

The third gate line 1310 may extend in the first direction (e.g., the x direction). The third gate line 1310 may correspond to the previous scan line SLp (e.g., see FIG. 6). In a plan view, the third gate line 1310 may be spaced apart from the first gate line 1210. The previous scan signal Sn-1 (e.g., see FIG. 6) may be provided to the third gate line 1310.

The fourth gate line 1320 may correspond to the second scan line SL2 (e.g., see FIG. 6). In a plan view, the fourth gate line 1320 may be spaced apart from the first gate line 1210 and the third gate line 1310. The second scan signal Sn′ (e.g., see FIG. 6) may be provided to the fourth gate line 1320.

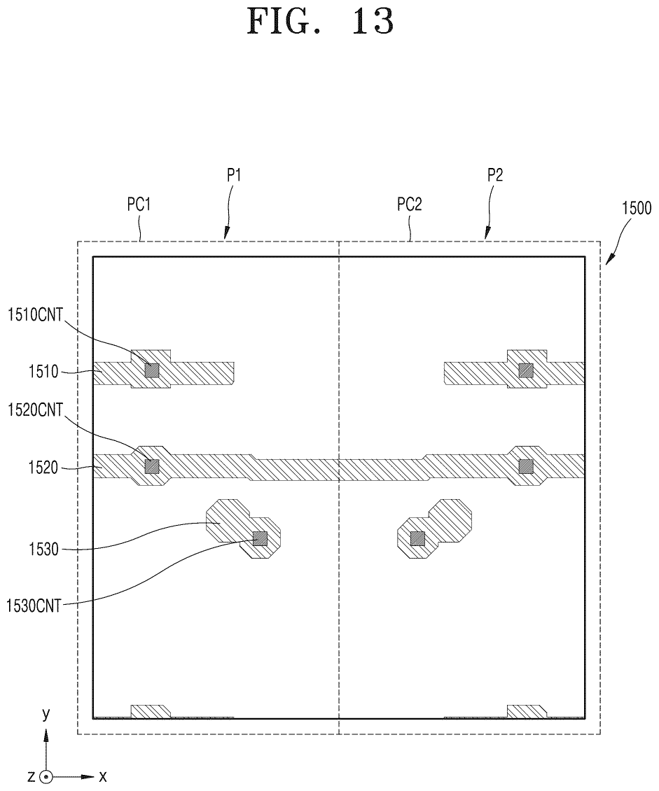

The capacitor electrode 1330 may overlap with the first gate electrode 1220. The capacitor electrode 1330 may overlap with at least a portion of a first transfer pattern 1530 (e.g., see FIG. 13) described in more detail below. The capacitor electrode 1330 may be arranged between the first gate electrode 1220 and the first transfer pattern 1530 (e.g., see FIG. 13). The capacitor electrode 1330 may have an opening 1330OP passing through the capacitor electrode 1330. The opening 1330OP defined in the capacitor electrode 1330 may expose a portion of the first gate electrode 1220. A portion of the capacitor electrode 1330 may be included in the first pixel circuit PC1, and another portion of the capacitor electrode 1330 may be included in the second pixel circuit PC2. A portion of the capacitor electrode 1330 corresponding to the first pixel circuit PC1 and a portion of the capacitor electrode 1330 corresponding to the second pixel circuit PC2 may be symmetrical or substantially symmetrical to each other with respect to an imaginary line.

The capacitor electrode 1330 and the first gate electrode 1220 may constitute the storage capacitor Cst. In other words, the storage capacitor Cst may include the first gate electrode 1220 and the capacitor electrode 1330. The first gate electrode 1220 may be the gate electrode of the driving thin-film transistor T1, and may be the first electrode CE1 of the storage capacitor Cst. The capacitor electrode 1330 may be the second electrode CE2 of the storage capacitor Cst. The driving voltage ELVDD may be provided to the capacitor electrode 1330.

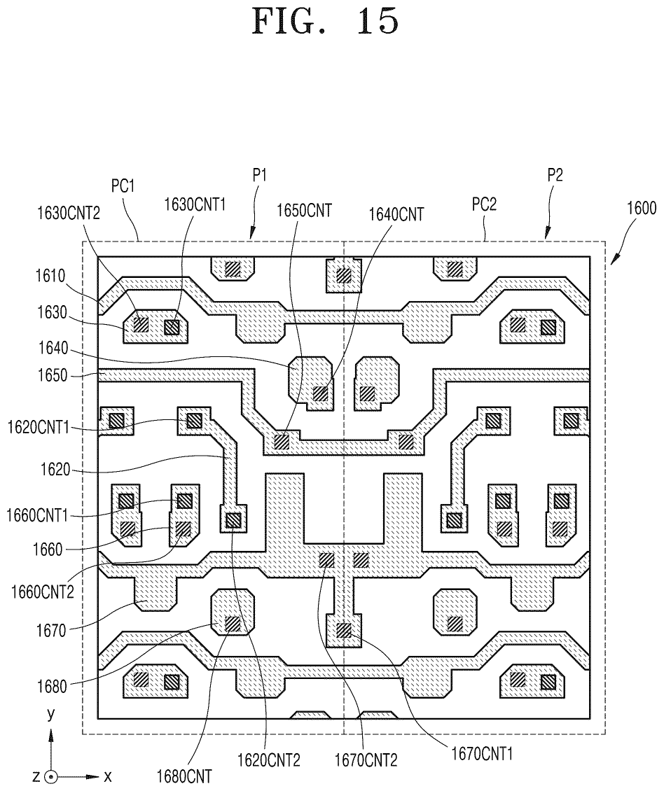

The first initialization voltage line 1340 may extend in the first direction (e.g., the x direction). In a plan view, the first initialization voltage line 1340 may be spaced apart from the third gate line 1310. The first initialization voltage Vint1 may be provided through the first initialization voltage line 1340. The first initialization voltage line 1340 may at least partially overlap with a second semiconductor layer 1400 described in more detail below, and may transfer the first initialization voltage Vint1 to the second semiconductor layer 1400. The first initialization voltage line 1340 may be electrically connected to the second semiconductor layer 1400 through contact holes 1630CNT1 and 1630CNT2 defined in a third transfer pattern 1630, which is described in more detail below with reference to FIG. 15. The first initialization voltage line 1340 may be the first initialization voltage line VL1 of FIG. 6.

The second conductive layer 1300 may contain, for example, a metal, an alloy, a conductive metal oxide, a transparent conductive material, or the like.

The first interlayer insulating layer 130 (e.g., see FIG. 17) may cover the second conductive layer 1300, and may be disposed on the second gate insulating layer 120. The first interlayer insulating layer 130 may be disposed on the third gate line 1310, the fourth gate line 1320, the capacitor electrode 1330, and the first initialization voltage line 1340. The first interlayer insulating layer 130 may be arranged between the second conductive layer 1300 and the second semiconductor layer 1400 that is described in more detail below. For example, the first interlayer insulating layer 130 may be arranged between the capacitor electrode 1330 and the second semiconductor layer 1400. The first interlayer insulating layer 130 may contain an insulating material. For example, the first interlayer insulating layer 130 may contain silicon oxide, silicon nitride, silicon oxynitride, aluminum oxide, or the like.

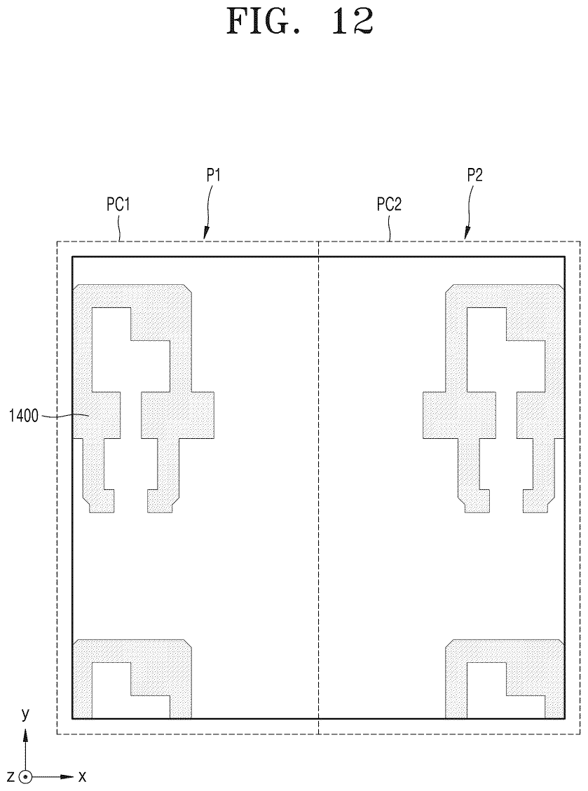

FIG. 12 shows the second semiconductor layer 1400.

Referring to FIG. 12 together with FIGS. 7 and 17, the second semiconductor layer 1400 may be disposed on the first interlayer insulating layer 130. The second semiconductor layer 1400 may be disposed on the second conductive layer 1300. In the present embodiment, the second semiconductor layer 1400 may include an oxide semiconductor. The second semiconductor layer 1400 may be disposed at (e.g., in or on) a layer different from that of which the first semiconductor layer 1100 is disposed. The second semiconductor layer 1400 may not overlap with the first semiconductor layer 1100.

A third gate insulating layer 140 (e.g., see FIG. 17) may cover the second semiconductor layer 1400, and may be disposed on the first interlayer insulating layer 130. The third gate insulating layer 140 may be arranged between the second semiconductor layer 1400 and a third conductive layer 1500 that is described in more detail below. The third gate insulating layer 140 may contain an insulating material. For example, the third gate insulating layer 140 may contain silicon oxide, silicon nitride, silicon oxynitride, aluminum oxide, or the like.

In an embodiment, as shown in FIG. 17, the third gate insulating layer 140 may cover the entire or substantially the entire second semiconductor layer 1400. In another embodiment, the third gate insulating layer 140 may be a pattern to cover a portion of the second semiconductor layer 1400, and may expose the remaining portion. For example, the third gate insulating layer 140 may include the same or substantially the same pattern as that of the third conductive layer 1500.

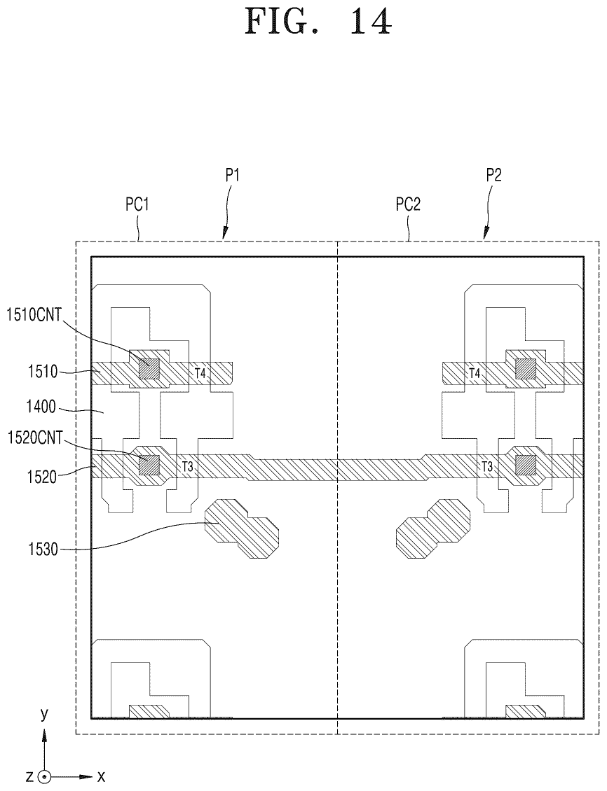

FIG. 13 shows the third conductive layer 1500. FIG. 14 shows an arrangement of the compensation thin-film transistor T3 and the first initialization thin-film transistor T4, and shows the second semiconductor layer 1400 of FIG. 12 and the third conductive layer 1500 of FIG. 13 together.

Referring to FIGS. 13 and 14 together with FIGS. 7 and 17, the third conductive layer 1500 may be disposed on the third gate insulating layer 140. The third conductive layer 1500 may be disposed on the second semiconductor layer 1400. The third conductive layer 1500 may include a second gate electrode 1510, a fifth gate line 1520, and a first transfer pattern 1530. In other words, the second gate electrode 1510, the fifth gate line 1520, and the first transfer pattern 1530 may be arranged at (e.g., in or on) the same layer as each other.

The second gate electrode 1510 (e.g., a gate pattern) may overlap with the third gate line 1310 and the second semiconductor layer 1400. In the present embodiment, the second gate electrode 1510 may be electrically connected to the third gate line 1310. For example, the second gate electrode 1510 may be in contact with the third gate line 1310 through a contact hole 1510CNT. The second gate electrode 1510 may include a contact portion in the contact hole 1510CNT, and the contact portion of the second gate electrode 1510 may be in contact with the third gate line 1310. The contact hole 1510CNT, which overlaps with the second gate electrode 1510, may pass through insulating layers (e.g., the first interlayer insulating layer 130 and the third gate insulating layer 140) arranged between the third gate line 1310 and the second gate electrode 1510.

The previous scan signal Sn-1 (e.g., see FIG. 6) may be provided to the second gate electrode 1510. The third gate line 1310, the second semiconductor layer 1400, and the second gate electrode 1510 may constitute the first initialization thin-film transistor T4. The first initialization thin-film transistor T4 may include the second semiconductor layer 1400, and the second gate electrode 1510 overlapping with at least a portion of the second semiconductor layer 1400. The first initialization thin-film transistor T4 may include the second semiconductor layer 1400, the second gate electrode 1510, and the third gate line 1310 at least partially overlapping with the second semiconductor layer 1400. For example, the third gate line 1310 may correspond to a back-gate electrode of the first initialization thin-film transistor T4, and the second gate electrode 1510 may correspond to a gate electrode of the first initialization thin-film transistor T4.

The fifth gate line 1520 may extend in the first direction (e.g., the x direction). The fifth gate line 1520 may overlap with the fourth gate line 1320 and the second semiconductor layer 1400. In some embodiments, the fifth gate line 1520 may be electrically connected to the fourth gate line 1320. For example, the fifth gate line 1520 may be in contact with the fourth gate line 1320 through a contact hole 1520CNT. The fifth gate line 1520 may include a contact portion in the contact hole 1520CNT, and the contact portion of the fifth gate line 1520 may be in contact with the fourth gate line 1320. The contact hole 1520CNT, which overlaps with the fifth gate line 1520, may pass through insulating layers (e.g., the first interlayer insulating layer 130 and the third gate insulating layer 140) arranged between the fourth gate line 1320 and the fifth gate line 1520.

The second scan signal Sn′ (e.g., see FIG. 6) may be provided to the fifth gate line 1520. The fourth gate line 1320, the second semiconductor layer 1400, and the fifth gate line 1520 may constitute the compensation thin-film transistor T3. The compensation thin-film transistor T3 may include the second semiconductor layer 1400, and the fifth gate line 1520 overlapping with at least a portion of the second semiconductor layer 1400. A portion of the fifth gate line 1520 overlapping with the second semiconductor layer 1400 may be a gate electrode of the compensation thin-film transistor T3. The compensation thin-film transistor T3 may include the second semiconductor layer 1400, the fifth gate line 1520, and the fourth gate line 1320 at least partially overlapping with the second semiconductor layer 1400. For example, the fourth gate line 1320 may correspond to a back-gate electrode of the compensation thin-film transistor T3, and the fifth gate line 1520 may correspond to the gate electrode of the compensation thin-film transistor T3.

The first transfer pattern 1530 may be electrically connected to the first gate electrode 1220 through a contact hole 1530CNT. For example, the first transfer pattern 1530 may be in contact with the first gate electrode 1220 through the contact hole 1530CNT. The first transfer pattern 1530 may include a contact portion in the contact hole 1530CNT, and the contact portion of the first transfer pattern 1530 may be in contact with the first gate electrode 1220. The contact hole 1530CNT, which overlaps with the first transfer pattern 1530, may pass through insulating layers (e.g., the second gate insulating layer 120, the first interlayer insulating layer 130, and the third gate insulating layer 140) arranged between the first gate electrode 1220 and the first transfer pattern 1530.

Hereinafter, a plurality of insulating layers including the second gate insulating layer 120, the first interlayer insulating layer 130, and the third gate insulating layer 140 may be referred to as an insulating structure IS (e.g., see FIG. 17). In other words, the insulating structure IS through which the contact hole 1530CNT defined in the first transfer pattern 1530 passes may include the second gate insulating layer 120, the first interlayer insulating layer 130, and the third gate insulating layer 140. The second gate insulating layer 120, the first interlayer insulating layer 130, and the third gate insulating layer 140 may be referred to as a first insulating layer, a second insulating layer, and a third insulating layer, respectively, of the insulating structure IS. The insulating structure IS may be arranged between the first conductive layer 1200 and the third conductive layer 1500. For example, as shown in FIG. 17, the insulating structure IS may be arranged between the first gate electrode 1220 and the fifth gate line 1520. For example, the insulating structure IS may be arranged between the first gate electrode 1220 and the second gate electrode 1510.

The contact hole 1530CNT overlapping with the first transfer pattern 1530 may overlap with the opening 1330OP defined in the capacitor electrode 1330. The first transfer pattern 1530 may be in contact with the first gate electrode 1220 exposed through the opening 1330OP defined in the capacitor electrode 1330.

The first transfer pattern 1530 may be electrically connected to a second transfer pattern 1620 (e.g., see FIG. 15) described in more detail below. As the second transfer pattern 1620 (e.g., see FIG. 15) connects the first transfer pattern 1530 and the second semiconductor layer 1400 to each other, the second semiconductor layer 1400 and the first gate electrode 1220 may be electrically connected to each other. As a third transfer pattern 1630 (e.g., see FIG. 15), which is described in more detail below, connects the second semiconductor layer 1400 and the first initialization voltage line 1340 to each other, the first transfer pattern 1530 may transfer the first initialization voltage Vint1 to the first gate electrode 1220.

A second interlayer insulating layer 150 (e.g., see FIG. 17) may cover the third conductive layer 1500, and may be disposed on the third gate insulating layer 140. The second interlayer insulating layer 150 may be arranged between the third conductive layer 1500 and a fourth conductive layer 1600 that is described in more detail below. The second interlayer insulating layer 150 may contain an insulating material. For example, the second interlayer insulating layer 150 may contain silicon oxide, silicon nitride, silicon oxynitride, aluminum oxide, or the like.

FIG. 15 shows the fourth conductive layer 1600.

Referring to FIG. 15 together with FIGS. 7 and 17, the fourth conductive layer 1600 may be disposed on the second interlayer insulating layer 150. The fourth conductive layer 1600 may be disposed on the third conductive layer 1500. For example, a first connection line 1610 may be disposed on the second gate electrode 1510. The fourth conductive layer 1600 may include the first connection line 1610, the second transfer pattern 1620, the third transfer pattern 1630, a fourth transfer pattern 1640, a second initialization voltage line 1650, a fifth transfer pattern 1660, a sixth transfer pattern 1670, and a seventh transfer pattern 1680. In other words, the first connection line 1610, the second transfer pattern 1620, the third transfer pattern 1630, the fourth transfer pattern 1640, the second initialization voltage line 1650, the fifth transfer pattern 1660, the sixth transfer pattern 1670, and the seventh transfer pattern 1680 may be arranged at (e.g., in or on) the same layer as each other.

The first connection line 1610 may extend in the first direction (e.g., the x direction). The data signal Dm (e.g., see FIG. 6) may be provided to the first connection line 1610.

The second transfer pattern 1620 may be disposed on the first transfer pattern 1530, and may overlap with a portion of the first transfer pattern 1530. The second transfer pattern 1620 may electrically connect the second semiconductor layer 1400 and the first transfer pattern 1530 to each other. The second transfer pattern 1620 may be electrically connected to the second semiconductor layer 1400 and the first transfer pattern 1530. For example, the second transfer pattern 1620 may be in contact with the second semiconductor layer 1400 and the first transfer pattern 1530 through contact holes 1620CNT1 and 1620CNT2, respectively, that are positioned on one side and another side of the second transfer pattern 1620. The second transfer pattern 1620 may include contact portions arranged in the contact holes 1620CNT1 and 1620 CNT2 that are positioned on one side and the other side of the second transfer pattern 1620, respectively. The contact portion on one side of the second transfer pattern 1620 may be in contact with the second semiconductor layer 1400, and the contact portion on the other side of the second transfer pattern 1620 may be in contact with the first transfer pattern 1530. The contact hole 1620CNT1, which overlaps with the second semiconductor layer 1400 on one side of the second transfer pattern 1620 may pass through an insulating layer (e.g., the third gate insulating layer 140 and the second interlayer insulating layer 150) arranged between the second semiconductor layer 1400 and the second transfer pattern 1620. The contact hole 1620CNT2, which overlaps with the first transfer pattern 1530 on the other side of the second transfer pattern 1620, may pass through an insulating layer (e.g., the second interlayer insulating layer 150) arranged between the first transfer pattern 1530 and the second transfer pattern 1620.

The third transfer pattern 1630 may be electrically connected to the second semiconductor layer 1400 and the first initialization voltage line 1340. For example, the third transfer pattern 1630 may respectively be in contact with the second semiconductor layer 1400 and the first initialization voltage line 1340 through contact holes 1630CNT1 and 1630CNT2 that are positioned on one side and another side of the third transfer pattern 1630. The third transfer pattern 1630 may include contact portions respectively arranged in the contact holes 1630CNT1 and 1630CNT2 that are positioned on one side and the other side of the third transfer pattern 1630. The contact portion on one side of the third transfer pattern 1630 may be in contact with the second semiconductor layer 1400, and the contact portion on the other side of the third transfer pattern 1630 may be in contact with the first initialization voltage line 1340. Accordingly, the third transfer pattern 1630 may transfer the first initialization voltage Vint1 to the first initialization thin-film transistor T4. The contact hole 1630CNT1 overlapping with the second semiconductor layer 1400 on one side of the third transfer pattern 1630 may pass through insulating layers (e.g., the third gate insulating layer 140 and the second interlayer insulating layer 150) arranged between the second semiconductor layer 1400 and the third transfer pattern 1630. The contact hole 1620CNT2 overlapping with the first initialization voltage line 1340 on the other side of the third transfer pattern 1630 may pass through an insulating layer (e.g., the first interlayer insulating layer 130, the third gate insulating layer 140, and the second interlayer insulating layer 150) arranged between the first initialization voltage line 1340 and the third transfer pattern 1630.

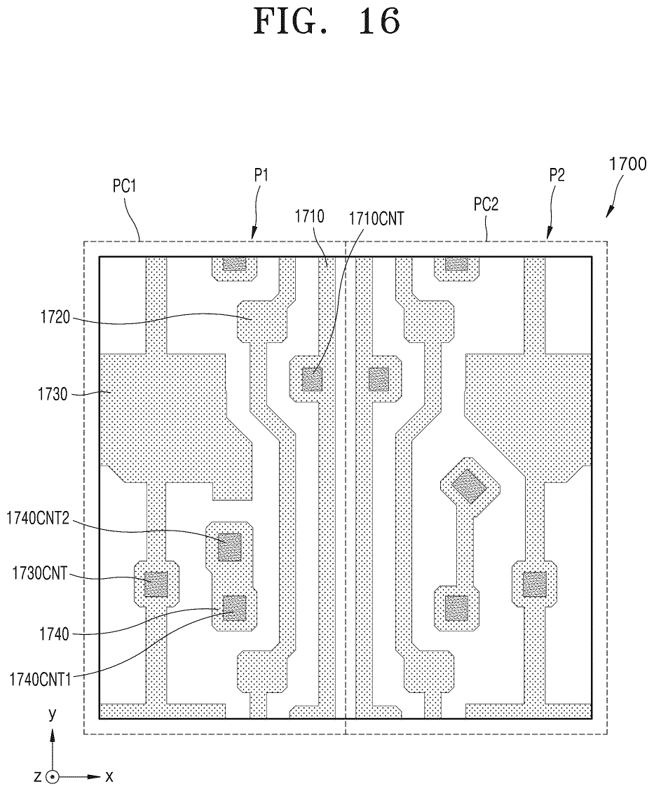

The fourth transfer pattern 1640 may be electrically connected to the first semiconductor layer 1100. For example, the fourth transfer pattern 1640 may be in contact with the first semiconductor layer 1100 through a contact hole 1640CNT. The fourth transfer pattern 1640 may include a contact portion in the contact hole 1640CNT, and the contact portion of the fourth transfer pattern 1640 may be in contact with the first semiconductor layer 1100. The fourth transfer pattern 1640 may be electrically connected to a data line 1710 (e.g., see FIG. 16) described in more detail below. Accordingly, the data signal Dm provided to the data line 1710 may be transferred to the first semiconductor layer 1100 through the fourth transfer pattern 1640. The contact hole 1640CNT, which overlaps with the fourth transfer pattern 1640, may pass through insulating layers (e.g., the first gate insulating layer 110, the second gate insulating layer 120, the first interlayer insulating layer 130, the third gate insulating layer 140, and the second interlayer insulating layer 150) arranged between the first semiconductor layer 1100 and the fourth transfer pattern 1640.

The second initialization voltage line 1650 (e.g., the second initialization voltage line VL2 of FIG. 6) may extend in the first direction (e.g., the x direction). The second initialization voltage Vint2 (e.g., see FIG. 6) may be provided to the second initialization voltage line 1650. The second initialization voltage line 1650 may be in contact with the first semiconductor layer 1100 through a contact hole 1650CNT, and may transfer the second initialization voltage Vint2 to the first semiconductor layer 1100. The second initialization voltage line 1650 may include a contact portion in the contact hole 1650CNT, and the contact portion of the second initialization voltage line 1650 may be in contact with the first semiconductor layer 1100. The contact hole 1650CNT, which overlaps with the second initialization voltage line 1650, may pass through insulating layers (e.g., the first gate insulating layer 110, the second gate insulating layer 120, the first interlayer insulating layer 130, the third gate insulating layer 140, and the second interlayer insulating layer 150) arranged between the second initialization voltage line 1650 and the first semiconductor layer 1100.

The fifth transfer pattern 1660 may be electrically connected to the second semiconductor layer 1400 and the first semiconductor layer 1100. For example, the fifth transfer pattern 1660 may respectively be in contact with the second semiconductor layer 1400 and the first semiconductor layer 1100 through contact holes 1660CNT1 and 1660 CNT2 that are positioned on one side and another side of the fifth transfer pattern 1660. The fifth transfer pattern 1660 may include contact portions arranged in the contact holes 1660CNT1 and 1660CNT2 that are respectively positioned on one side and the other side of the fifth transfer pattern 1660. The contact portion on one side of the fifth transfer pattern 1660 may be in contact with the second semiconductor layer 1400, and the contact portion on the other side of the fifth transfer pattern 1660 may be in contact with the first semiconductor layer 1100. Accordingly, the fifth transfer pattern 1660 may electrically connect the second semiconductor layer 1400 and the first semiconductor layer 1100 to each other. The contact hole 1660CNT1 overlapping with the second semiconductor layer 1400 on one side of the fifth transfer pattern 1660 may pass through insulating layers (e.g., the third gate insulating layer 140 and the second interlayer insulating layer 150) arranged between the second semiconductor layer 1400 and the fifth transfer pattern 1660. The contact hole 1660CNT2 overlapping with the first semiconductor layer 1100 on the other side of the fifth transfer pattern 1660 may pass through an insulating layer (e.g., the first gate insulating layer 110, the second gate insulating layer 120, first interlayer insulating layer 130, the third gate insulating layer 140, and the second interlayer insulating layer 150) arranged between the first gate insulating layer 110 and the fifth transfer pattern 1660.

The sixth transfer pattern 1670 may extend in the first direction (e.g., the x direction). The sixth transfer pattern 1670 may be electrically connected to the first semiconductor layer 1100 and the capacitor electrode 1330. For example, the sixth transfer pattern 1670 may respectively be in contact with the first semiconductor layer 1100 and the capacitor electrode 1330 through contact holes 1670CNT1 and 1670CNT2 that are positioned on one side and another side of the sixth transfer pattern 1670. The sixth transfer pattern 1670 may include contact portions arranged in the contact holes 1670CNT1 and 1670CNT2 that are respectively positioned on one side and the other side of the sixth transfer pattern 1670. The contact portion on one side of the sixth transfer pattern 1670 may be in contact with the first semiconductor layer 1100, and the contact portion on the other side of the sixth transfer pattern 1670 may be in contact with capacitor electrode 1330. The driving voltage ELVDD may be provided to the sixth transfer pattern 1670 through a voltage line 1730 (e.g., see FIG. 16) described in more detail below. Because the sixth transfer pattern 1670 may be in contact with the first semiconductor layer 1100 through the contact hole 1670CNT1, the driving voltage ELVDD may be transferred to the first semiconductor layer 1100. The contact hole 1670CNT1, which overlaps with the first semiconductor layer 1100 on one side of the sixth transfer pattern 1670, may pass through insulating layers (e.g., the first gate insulating layer 110, the second gate insulating layer 120, the first interlayer insulating layer 130, the third gate insulating layer 140, and the second interlayer insulating layer 150) arranged between the first semiconductor layer 1100 and the sixth transfer pattern 1670. The contact hole 1670CNT2, which overlaps with the capacitor electrode 1330 on the other side of the sixth transfer pattern 1670, may pass through an insulating layer (e.g., the first interlayer insulating layer 130, the third gate insulating layer 140, and the second interlayer insulating layer 150) arranged between the capacitor electrode 1330 and the sixth transfer pattern 1670.

The seventh transfer pattern 1680 may be electrically connected to the first semiconductor layer 1100. For example, the seventh transfer pattern 1680 may be in contact with the first semiconductor layer 1100 through a contact hole 1680CNT. The seventh transfer pattern 1680 may include a contact portion in the contact hole 1680CNT, and the contact portion of the seventh transfer pattern 1680 may be in contact with the first semiconductor layer 1100. The seventh transfer pattern 1680 may transfer a driving current or the second initialization voltage Vint2 from the first semiconductor layer 1100 to the organic light-emitting diode OLED.

A first planarization insulating layer 160 (e.g., see FIG. 17) may cover the fourth conductive layer 1600, and may be disposed on the second interlayer insulating layer 150. The first planarization insulating layer 160 may be arranged between the fourth conductive layer 1600 and a fifth conductive layer 1700 (e.g., see FIG. 16) that is described in more detail below. The first planarization insulating layer 160 may contain an organic insulating material. For example, the first planarization insulating layer 160 may contain a photoresist, a polyacryl-based resin, a polyimide-based resin, an acryl-based resin, or the like.

Referring to FIG. 16 together with FIGS. 7 and 17, the fifth conductive layer 1700 may be disposed on the first planarization insulating layer 160. The fifth conductive layer 1700 may be disposed on the fourth conductive layer 1600. The fifth conductive layer 1700 may include the data line 1710, a second connection line 1720, a voltage line 1730, and an eighth transfer pattern 1740. In other words, the data line 1710, the second connection line 1720, the voltage line 1730, and the eighth transfer pattern 1740 may be arranged at (e.g., in or on) the same layer as each other.

The data line 1710 may extend in the second direction (e.g., the y direction). The data line 1710 may correspond to the data line DL of FIG. 6. The data line 1710 may be connected to the fourth transfer pattern 1640 through a contact hole 1710CNT. The data signal Dm may be transferred to the first semiconductor layer 1100 through the data line 1710 and the fourth transfer pattern 1640.

The second connection line 1720 may extend in the second direction (e.g., the y direction). The second connection line 1720 may be disposed on the first connection line 1610. In an embodiment, the second connection line 1720 may be in contact with the first connection line 1610. The second connection line 1720 may be electrically connected to the first connection line 1610.

In an embodiment, the first connection line 1610 may correspond to the first connection lines DH1 to DH3, the data line 1710 may correspond to the first to sixth data lines DL1 to DL6, and the second connection line 1720 may correspond to the second connection lines DV1 to DV3 or the third connection lines DV1′ to DV3′, which are described above with reference to FIG. 5.

For example, the data line 1710 and the second connection line 1720 may receive different data voltages from each other. For example, a first data voltage may be transferred to the first semiconductor layer 1100 through the data line 1710, and a second data voltage, which is different from the first data voltage, may be transferred to the first connection line 1610 through the second connection line 1720. The same data signal may be applied to the first connection line 1610 and the second connection line 1720.

The voltage line 1730 may extend in the second direction (e.g., the y direction). The voltage line 1730 may correspond to the driving voltage line PL of FIG. 6. The voltage line 1730 may provide the driving voltage ELVDD. The voltage line 1730 may be connected to the sixth transfer pattern 1670 through a contact hole 1730CNT, and may provide the driving voltage ELVDD to the capacitor electrode 1330 and the operation control thin-film transistor T5.

In an embodiment, the voltage line 1730 may be provided in each of the first pixel circuit PC1 and the second pixel circuit PC2. In another embodiment, the voltage line 1730 may be shared by the first pixel circuit PC1 and the second pixel circuit PC2, which are adjacent to each other.

The eighth transfer pattern 1740 may be in contact with the seventh transfer pattern 1680 through a contact hole 1740CNT1 on one side thereof. The eighth transfer pattern 1740 may transfer the driving current IOLED or the second initialization voltage Vint2 from the seventh transfer pattern 1680 to the organic light-emitting diode OLED.

In addition, the eighth transfer pattern 1740 may be in contact with a pixel electrode 210 (e.g., see FIG. 17) through a contact hole 1740CNT2 on the other side. The emission control thin-film transistor T6 may be electrically connected to the pixel electrode 210 through the eighth transfer pattern 1740.

A second planarization layer 170 may cover the fifth conductive layer 1700, and may be disposed on the first planarization insulating layer 160. The second planarization layer 170 may contain an organic insulating material. For example, the first planarization insulating layer 160 and the second planarization layer 170 may contain general-purpose polymers, such as benzocyclobutene (BCB), polyimide, hexamethyldisiloxane (HMDSO), polymethylmethacrylate (PMMA), or polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, and/or any suitable blends thereof.

Referring to FIG. 17, the organic light-emitting diode OLED may be disposed on the second planarization layer 170. The organic light-emitting diode OLED may include the pixel electrode 210, an intermediate layer 220 that includes an organic emission layer, and an opposite electrode 230.

The pixel electrode 210 may be a (semi-) transmissive electrode or a reflective electrode. In an embodiment, the pixel electrode 210 may include a reflective layer containing Ag, magnesium (Mg), Al, Pt, palladium (Pd), gold (Au), Ni, neodymium (Nd), iridium (Ir), Cr, or the like, and a transparent or translucent electrode layer formed on the reflective layer. The transparent or translucent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 210 may be provided as ITO/Ag/ITO.

A pixel-defining layer 180 may be disposed on the second planarization layer 170. The pixel-defining layer 180 may prevent or substantially prevent an arc or the like from occurring at an edge of the pixel-defining layer 180 by increasing a distance between an edge of the pixel electrode 210 and the opposite electrode 230 that is on the pixel electrode 210.

The pixel-defining layer 180 may contain one or more organic insulating materials selected from the group consisting of polyimide, polyamide, acryl-based resin, BCB, and phenolic resin, and may be formed by spin coating or the like.

The intermediate layer 220 of the organic light-emitting diode OLED may be arranged in an opening 180OP formed by the pixel-defining layer 180. An emission area EA of the organic light-emitting diode OLED may be defined by the opening 180OP defined in the pixel-defining layer 180.

The intermediate layer 220 may include an organic emission layer. The organic emission layer may contain an organic material containing a fluorescent or a phosphorous material that emits red, green, blue, or white light. The organic emission layer may be a low-molecular weight organic material or a polymer organic material. Under and over the organic emission layer, a functional layer, such as a hole transport layer (HTL), a hole injection layer (HIL), an electron transport layer (ETL), and/or an electron injection layer (EIL), may be further selectively disposed.

The organic emission layer may be arranged to correspond to each pixel electrode 210 provided for each pixel P. In addition to the organic emission layer, the intermediate layer 220 may include a layer that is integrated across a plurality of pixel electrodes 210, and various suitable modifications may be made.

The opposite electrode 230 may be a light-transmitting electrode or a reflective electrode. In some embodiments, the opposite electrode 230 may be a transparent or translucent electrode, and may include a metal thin film having a low work function including lithium (Li), calcium (Ca), lithium fluoride/calcium (LiF/Ca), LIF/AI, AI, Ag, Mg, and/or a suitable compound thereof. In addition, a transparent conductive oxide (TCO) film containing ITO, IZO, ZnO, or In₂O₃ may be further disposed on the metal thin film. The opposite electrode 230 may be integrally formed across the entire or substantially the entire surface of the display area DA, and may be disposed over the intermediate layer 220 and the pixel-defining layer 180.

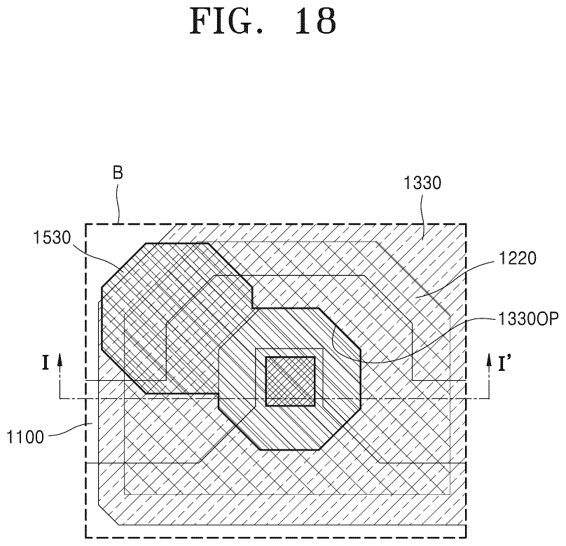

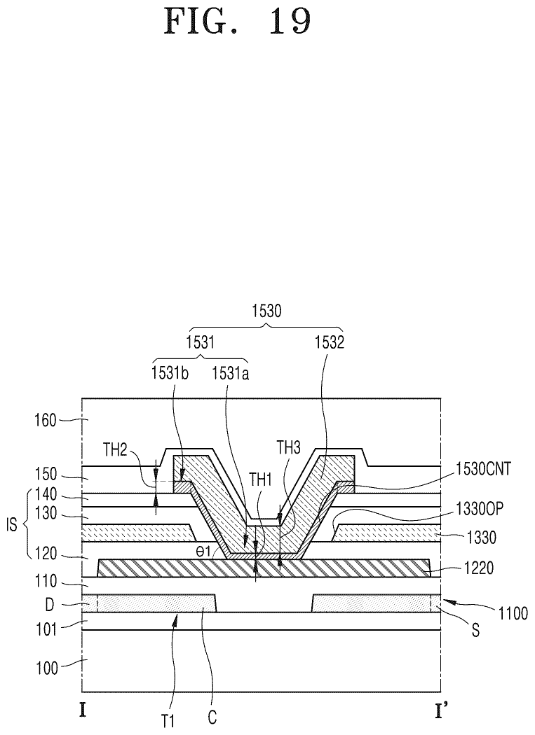

FIG. 18 is an enlarged plan view schematically illustrating some layers in the region B of FIG. 7. FIG. 19 is a cross-sectional view schematically illustrating a cross-section taken along the line I-I′ of FIG. 18.

Referring to FIGS. 18 and 19, the first semiconductor layer 1100, the first gate electrode 1220, the capacitor electrode 1330, and the first transfer pattern 1530 are shown. A portion of the first gate electrode 1220 may overlap with the first semiconductor layer 1100, and may constitute the driving thin-film transistor T1. The first semiconductor layer 1100 may include a channel region C overlapping with the first gate electrode 1220, and a source region S and a drain region D that are arranged on opposite sides, respectively, of the channel region C. The first gate electrode 1220 and the capacitor electrode 1330 may constitute the storage capacitor Cst.

The first gate electrode 1220 may be disposed on the first gate insulating layer 110. The insulating structure IS may be disposed on the first gate electrode 1220. The insulating structure IS may be arranged between the first gate electrode 1220 and the first transfer pattern 1530. The insulating structure IS may include the second gate insulating layer 120, the first interlayer insulating layer 130, and the third gate insulating layer 140. The second gate insulating layer 120 may be disposed on the first gate electrode 1220. The second gate insulating layer 120 may be arranged between the first gate electrode 1220 and the capacitor electrode 1330. The first interlayer insulating layer 130 may be disposed on the capacitor electrode 1330. The first interlayer insulating layer 130 may be arranged between the capacitor electrode 1330 and the third gate insulating layer 140. The first interlayer insulating layer 130 may be arranged between the capacitor electrode 1330 and the first transfer pattern 1530. The third gate insulating layer 140 may be arranged between the first transfer pattern 1530 and the first interlayer insulating layer 130.

Hereinafter, a slope of an inner wall of the insulating structure IS formed by the contact hole 1530CNT that passes through (e.g., that penetrates) the insulating structure IS may be referred to as a taper angle θ1. In other words, the taper angle θ1 of the insulating structure IS may be an angle between an upper surface of the first gate electrode 1220 and an inner wall of the insulating structure IS in an area in which the upper surface of the first gate electrode 1220 and the first transfer pattern 1530 overlap with each other. The first transfer pattern 1530 may be disposed on the inner wall of the insulating structure IS.

The taper angle θ1 of the insulating structure IS may be in a range of about 40° to about 75°. Because the taper angle θ1 of the insulating structure IS may be formed to be about 75° or less, a thickness TH1 of a first portion 1531a of a first layer 1531 of the first transfer pattern 1530 described in more detail below may be formed to be relatively large. When the taper angle θ1 of the insulating structure IS is less than about 40°, a size of the first transfer pattern 1530 may become excessively large, making it more difficult to implement a high resolution.

At least a portion of the first transfer pattern 1530 may overlap with the driving thin-film transistor T1. The first transfer pattern 1530 may be electrically connected to the first gate electrode 1220 through the contact hole 1530CNT passing through (e.g., penetrating) the insulating structure IS. A contact portion of the first transfer pattern 1530 may overlap with the opening 1330OP defined in the capacitor electrode 1330. The first transfer pattern 1530 may be electrically connected to the first gate electrode 1220, which is exposed through the opening 1330OP defined in the capacitor electrode 1330.

The first transfer pattern 1530 may include the first layer 1531, and a second layer 1532 on the first layer 1531. The first layer 1531 and the second layer 1532 of the first transfer pattern 1530 may be referred to as a lower conductive layer and an upper conductive layer, respectively. Insulating layers arranged on a layer on which the first transfer pattern 1530 is arranged, for example, the second gate electrode 1510 and the fifth gate line 1520, may have a double-layered structure including a lower conductive layer and an upper conductive layer, similar to that of the first transfer pattern 1530.

The first layer 1531 of the first transfer pattern 1530 may contain a conductive material that adsorbs hydrogen (H). The first layer 1531 of the first transfer pattern 1530 may contain, for example, Ti.

The first layer 1531 of the first transfer pattern 1530 may include the first portion 1531a arranged in the contact hole 1530CNT, and a second portion 1531b arranged outside the contact hole 1530CNT. A thickness TH2 of the second portion 1531b of the first layer 1531 may be equal to or greater than the thickness TH1 of the first portion 1531a of the first layer 1531.

For example, the thickness TH1 of the first portion 1531a of the first layer 1531 may be in a range of about 200 Å to about 500 Å. For example, the thickness TH1 of the first portion 1531a of the first layer 1531 may be in a range of about 200 Å to about 450 Å. When the thickness TH1 of the first portion 1531a of the first layer 1531 is less than about 200 Å, as described in more detail below with reference to Table 1, a distribution of hydrogen adsorbed by the first layer 1531 of the first transfer pattern 1530 may not be uniform during a heat treatment process operation, which may cause stain defects. In an embodiment, the thickness TH1 of the first portion 1531a of the first layer 1531 of the first transfer pattern 1530 may be formed to be about 200 Å or more, and thus, stain defects may be reduced.

In an embodiment, because the taper angle θ1 of the insulating structure IS may be formed in a range of about 40° to about 75°, the thickness TH1 of the first portion 1531a of the first layer 1531 may be more easily formed to be about 200 Å or more.

For example, the thickness TH2 of the second portion 1531b of the first layer 1531 may be in a range of about 450 Å to about 800 Å. For example, the thickness TH2 of the second portion 1531b of the first layer 1531 may be in a range of about 500 Å to about 650 Å. When the thickness TH2 of the second portion 1531b of the first layer 1531 is less than 450 Å, the thickness TH1 of the first portion 1531a of the first layer 1531 may be formed to be less than 200 Å. In an embodiment, the thickness TH2 of the second portion 1531b of the first layer 1531 may be formed to be about 450 Å or more to reduce stain defects and improve a display quality of the display device. When the thickness TH1 of the first portion 1531a of the first layer 1531 and the thickness TH2 of the second portion 1531b exceed 800 Å, it may be more difficult to implement a thin display device.

Table 1 below shows a stain defect rate of a comparative example and some embodiments of the present disclosure in which a thickness of the first layer 1531 of the first transfer pattern 1530 is varied.

TABLE 1

| | Thickness of | | |
|---|---|---|---|
| | second portion | Thickness of first | |
| | 1531b | portion 1531a | Stain defect rate |
| Comparative | 300 Å | 150 Å | 25% |
| Example | | | |
| Example 1 | 450 Å | 230 Å | 3% |
| Example 2 | 500 Å | 280 Å | 0.6% |
| Example 3 | 600 Å | 350 Å | |

As shown in Table 1, a maximum thickness and a stain defect rate of the first portion 1531a that is formed when the thickness of the second portion 1531b of the first layer 1531 of the first transfer pattern 1530 is formed to be 300 Å, 450 Å, 500 Å, and 600 Å in a Comparative Example, an Example 1, an Example 2, and an Example 3, respectively, is illustrated. The stain defect rate is measured by a difference in a luminance around a stain.

Referring to Table 1, in the Comparative Example, when the thickness of the second portion 1531b of the first layer 1531 of the first transfer pattern 1530 is formed to be 300 Å, which is less than 450 Å, a maximum thickness of the first portion 1531a of the first layer 1531 is 150 Å, and a stain defect rate of the first portion 1531a of the first layer 1531 is 25%. In the Example 1, when the thickness of the second portion 1531b of the first layer 1531 of the first transfer pattern 1530 is formed to be 450 Å, the maximum thickness of the first portion 1531a of the first layer 1531 is 230 Å, and the stain defect rate of the first portion 1531a is 3%. Accordingly, when the thickness of the second portion 1531b of the first layer 1531 of the first transfer pattern 1530 is 450 Å or more, the thickness of the first portion 1531a of the first layer 1531 may be formed to be about 200 Å or more, and the defect rate may be significantly reduced when compared to when the thickness of the second portion 1531b is less than 450 Å.

In addition, according to the Example 2, when the thickness of the second portion 1531b of the first layer 1531 of the first transfer pattern 1530 is formed to be 500 Å, the maximum thickness of the first portion 1531a of the first layer 1531 is 280 Å, and the stain defect rate of the first portion 1531a is 0.6%. According to the Example 3, when the thickness of the second portion 1531b of the first layer 1531 of the first transfer pattern 1530 is formed to be 600 Å, the maximum thickness of the first portion 1531a of the first layer 1531 is 350 Å, and the stain defect rate of the first portion 1531a is 0.6%. As described above, when the thickness of the second portion 1531b of the first layer 1531 of the first transfer pattern 1530 is 500 Å or more, the maximum thickness of the first portion 1531a of the first layer 1531 may be increased in proportion to the thickness of the second portion 1531b, and the stain defect rate may saturate to about 0.6%.

Referring to FIGS. 18 and 19, the second layer 1532 of the first transfer pattern 1530 may contain a conductive material having a high conductivity. The second layer 1532 of the first transfer pattern 1530 may contain a metal, an alloy, a conductive metal oxide, a transparent conductive material, or the like. The second layer 1532 of the first transfer pattern 1530 may contain, for example, Mo, a Mo-containing alloy, Al, an Al-containing alloy, Aln, Ag, an Ag-containing alloy, W, WN, Cu, or the like.

A thickness TH3 of the second layer 1532 of the first transfer pattern 1530 may be greater than the thickness of the first layer 1531 of the first transfer pattern 1530. In other words, the thickness TH3 of the second layer 1532 of the first transfer pattern 1530 may be greater than the thickness of each of the first portion 1531a of the first layer 1531 and the second portion 1531b of the first layer 1531. In an embodiment, the thickness TH3 of the second layer 1532 of the first transfer pattern 1530 in a portion positioned in the contact hole 1530CNT may be the same or substantially the same as that of a portion positioned outside the contact hole 1530CNT. However, the present disclosure is not limited thereto. In another embodiment, the thickness TH3 of the second layer 1532 of the first transfer pattern 1530 may be greater in the portion positioned outside the contact hole 1530CNT than that of the portion positioned in the contact hole 1530CNT.

The second interlayer insulating layer 150 may be disposed on the first transfer pattern 1530.

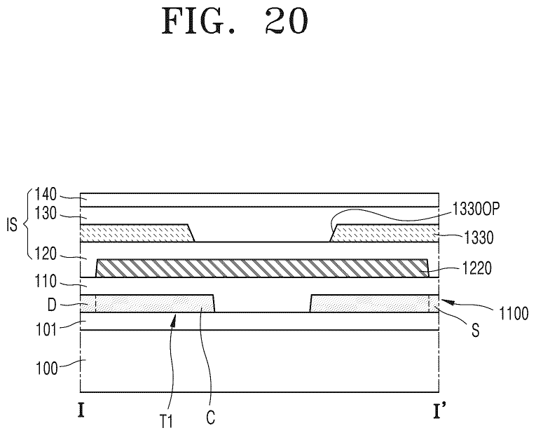

FIGS. 20 through 24 are cross-sectional views illustrating a method of manufacturing a display device, according to an embodiment. FIGS. 20 through 24 show a method of manufacturing the display device in the cross-sectional view corresponding to that of FIG. 19.

Referring to FIG. 20, the driving thin-film transistor T1 may be formed on the substrate 100. The first semiconductor layer 1100 may be formed on the substrate 100. The first gate insulating layer 110 may be formed on the first semiconductor layer 1100. The first gate electrode 1220 may be formed on the first gate insulating layer 110. At least a portion of the first gate electrode 1220 may be formed to overlap with the first semiconductor layer 1100.

In an embodiment, the first semiconductor layer 1100 may include a silicon semiconductor. For example, the silicon semiconductor may include amorphous silicon, polycrystalline silicon, or the like. For example, the first semiconductor layer 1100 may include LTPS.

The first gate insulating layer 110 may contain an insulating material. For example, the first gate insulating layer 110 may contain silicon oxide, silicon nitride, silicon oxynitride, aluminum oxide, or the like.

The first gate electrode 1220 may include a metal, an alloy, a conductive metal oxide, a transparent conductive material, or the like. For example, the first gate electrode 1220 may contain Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like.

Next, the second gate insulating layer 120 may be formed on the first gate electrode 1220. The second gate insulating layer 120 may be formed on the first gate insulating layer 110 to cover the first gate electrode 1220. The second gate insulating layer 120 may contain an insulating material. For example, the second gate insulating layer 120 may contain silicon oxide, silicon nitride, silicon oxynitride, aluminum oxide, or the like.

The capacitor electrode 1330 may be formed on the second gate insulating layer 120. At least a portion of the capacitor electrode 1330 may be formed to overlap with the first gate electrode 1220. The first gate electrode 1220 and the capacitor electrode 1330 may constitute a storage capacitor. The capacitor electrode 1330 may be formed to have an opening 1330OP that exposes a portion of the first gate electrode 1220. The capacitor electrode 1330 may contain, for example, a metal, an alloy, a conductive metal oxide, a transparent conductive material, or the like.

Next, the first interlayer insulating layer 130 may be formed on the capacitor electrode 1330. The first interlayer insulating layer 130 may be formed on the second gate insulating layer 120 to cover the capacitor electrode 1330. The first interlayer insulating layer 130 may be arranged in the opening 1330OP defined in the capacitor electrode 1330. For example, the first interlayer insulating layer 130 may contain silicon oxide, silicon nitride, silicon oxynitride, aluminum oxide, or the like.

Referring to FIGS. 20 and 17 together, the second semiconductor layer 1400 may be formed on the first interlayer insulating layer 130. The second semiconductor layer 1400 may be formed to not overlap with the first semiconductor layer 1100. The second semiconductor layer 1400 may include, for example, an oxide semiconductor.

1 Next, the third gate insulating layer 140 may be formed on the second semiconductor layer 1400. The third gate insulating layer 140 may be formed on the first interlayer insulating layer 130 to cover the second semiconductor layer 1400. For example, the third gate insulating layer 140 may contain silicon oxide, silicon nitride, silicon oxynitride, aluminum oxide, or the like.

Hereinafter, a plurality of insulating layers including the second gate insulating layer 120, the first interlayer insulating layer 130, and the third gate insulating layer 140 may be referred to as the insulating structure IS. The second gate insulating layer 120, the first interlayer insulating layer 130, and the third gate insulating layer 140 may be referred to as a first insulating layer, a second insulating layer, and a third insulating layer, respectively, of the insulating structure IS.

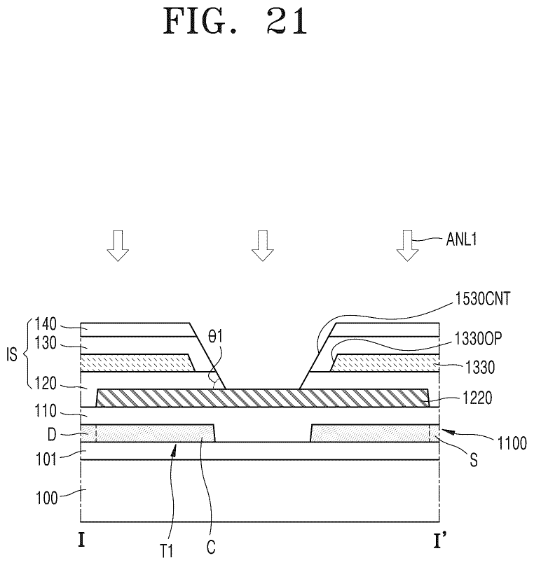

Referring to FIG. 21, the contact hole 1530CNT passing through (e.g., penetrating) the insulating structure IS may be formed. The contact hole 1530CNT of the insulating structure IS may be formed to overlap with the first gate electrode 1220. The contact hole 1530CNT of the insulating structure IS may be formed by removing a portion of each of the second gate insulating layer 120, the first interlayer insulating layer 130, and the third gate insulating layer 140 positioned in an area overlapping with the first gate electrode 1220. The contact hole 1530CNT passing through the insulating structure IS may be formed through an etching process (e.g., a dry etching process).

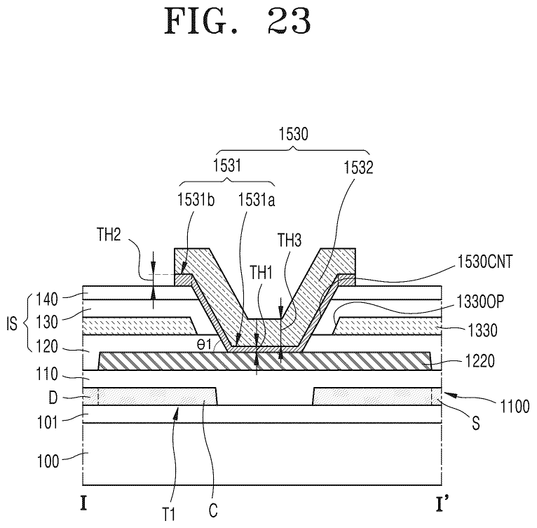

A slope of an inner wall of the insulating structure IS formed by removing the second gate insulating layer 120, the first interlayer insulating layer 130, and the third gate insulating layer 140 may be referred to as the taper angle θ1. The insulating structure IS may be formed to have the taper angle θ1 in a range of about 40° to about 75°. When the taper angle θ1 of the insulating structure IS is about 75° or less, a thickness of the first layer 1531 of a first transfer pattern 1530 (e.g., see FIG. 23) formed in a subsequent process may be formed to be large.

After the contact hole 1530CNT passing through the insulating structure IS is formed, a first heat treatment process ANL1 may be performed. In an embodiment, the first heat treatment process ANL1 may be performed within a temperature range of 370° C. to about 380° C. for about 10 minutes to about 30 minutes. By performing the first heat treatment process ANL1, hydrogen included in a plurality of insulating layers formed on the substrate 100 and the first semiconductor layer 1100 may be moved. The hydrogen moved by the first heat treatment process ANL1 may be adsorbed by the first layer 1531 (e.g., see FIG. 23) of the first transfer pattern 1530 formed according to a subsequent process.

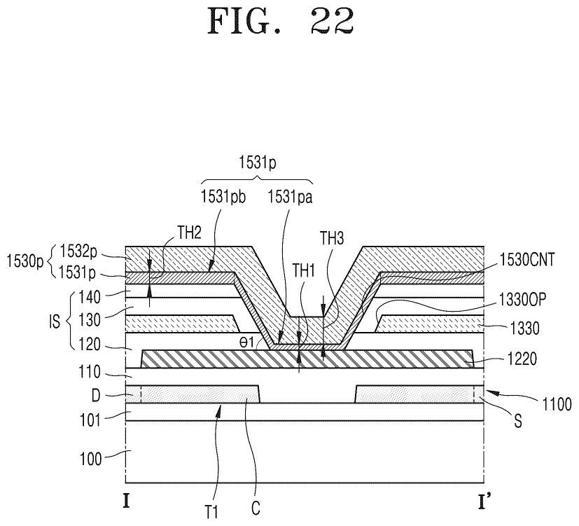

Referring to FIG. 22, a preliminary first transfer pattern 1530p may be formed on the insulating structure IS. The preliminary first transfer pattern 1530p may be formed on the third gate insulating layer 140. The preliminary first transfer pattern 1530p may be formed to be in contact with the first gate electrode 1220 through the contact hole 1530CNT.

The preliminary first transfer pattern 1530p may be formed to include a first preliminary layer 1531p, and a second preliminary layer 1532p on the first preliminary layer 1531p. In other words, the first preliminary layer 1531p may be formed on the insulating structure IS, and the second preliminary layer 1532p may be formed on the first preliminary layer 1531p.

The first preliminary layer 1531p may contain a conductive material that adsorbs H. The first preliminary layer 1531p may contain, for example, Ti.

The first preliminary layer 1531p may include a first portion 1531pa arranged in the contact hole 1530CNT, and a second portion 1531pb arranged outside the contact hole 1530CNT. For example, the thickness TH2 of the second portion 1531pb of the first preliminary layer 1531p may be formed in a range of about 450 Å to about 800 Å. When the thickness TH2 of the second portion 1531pb of the first preliminary layer 1531p is formed in the range of about 450 Å to about 800 Å, the thickness TH1 of the first portion 1531pa of the first preliminary layer 1531p may be formed in a range of about 200 Å to about 500 Å. Because the taper angle θ1 of the insulating structure IS may be formed to be about 75° or less, the thickness TH1 of the first portion 1531pa of the first preliminary layer 1531p may be more easily formed to be about 200 Å or more.

The second preliminary layer 1532p may contain a conductive material having a high conductivity. The second preliminary layer 1532p may contain a metal, an alloy, a conductive metal oxide, a transparent conductive material, or the like. The second preliminary layer 1532p may contain, for example, Mo, a Mo-containing alloy, Al, an Al-containing alloy, Aln, Ag, an Ag-containing alloy, W, WN, Cu, or the like.

Referring to FIG. 23, a first transfer pattern 1530 may be formed by etching the preliminary first transfer pattern 1530p of FIG. 22. When the first transfer pattern 1530 is formed by etching the preliminary first transfer pattern 1530p, the second gate electrode 1510 and the fifth gate line 1520 described above with reference to FIG. 13 may be concurrently or substantially simultaneously formed. In other words, the second gate electrode 1510 and the fifth gate line 1520 may be formed by etching the preliminary first transfer pattern 1530p. A process of forming the first transfer pattern 1530 by etching the preliminary first transfer pattern 1530p may be, for example, a dry etching process.

The first transfer pattern 1530 may be electrically connected to the first gate electrode 1220 through the contact hole 1530CNT. A contact portion of the first transfer pattern 1530 may overlap with the opening 1330OP defined in the capacitor electrode 1330. The first transfer pattern 1530 may be electrically connected to the first gate electrode 1220, which is exposed through the opening 1330OP defined in the capacitor electrode 1330.

The first transfer pattern 1530 may include the first layer 1531, and the second layer 1532 on the first layer 1531.

1 The first layer 1531 of the first transfer pattern 1530 may contain a conductive material that adsorbs H. The first layer 1531 of the first transfer pattern 1530 may contain, for example, Ti.

The first layer 1531 of the first transfer pattern 1530 may include the first portion 1531a arranged in the contact hole 1530CNT, and the second portion 1531b arranged outside the contact hole 1530CNT. For example, the thickness TH2 of the second portion 1531b of the first layer 1531 of the first transfer pattern 1530 may be formed in the range of about 450 Å to about 800 Å. When the thickness TH2 of the second portion 1531b of the first layer 1531 of the first transfer pattern 1530 is in the range of about 450 Å to about 800 Å, the thickness TH1 of the first portion 1531a of the first layer 1531 of the first transfer pattern 1530 may be in the range of about 200 Å to about 500 Å.

The second layer 1532 of the first transfer pattern 1530 may contain a conductive material having a high conductivity. The second layer 1532 of the first transfer pattern 1530 may contain a metal, an alloy, a conductive metal oxide, a transparent conductive material, or the like. The second layer 1532 of the first transfer pattern 1530 may contain, for example, Mo, a Mo-containing alloy, Al, an Al-containing alloy, Aln, Ag, an Ag-containing alloy, W, WN, Cu, or the like.

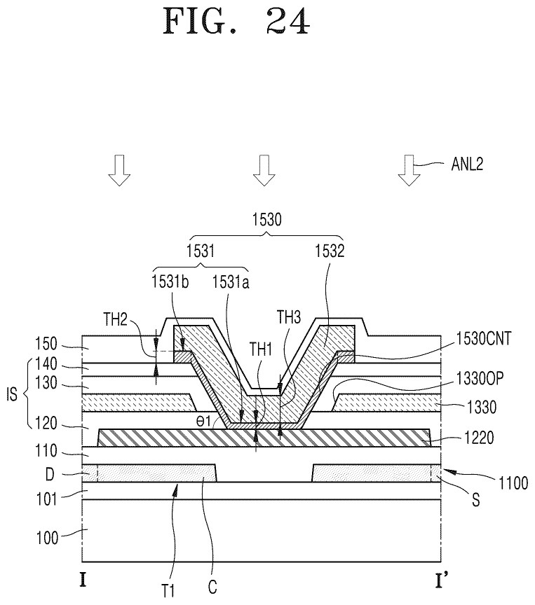

Referring to FIG. 24, the second interlayer insulating layer 150 may be formed on the first transfer pattern 1530. The second interlayer insulating layer 150 may be formed on the third gate insulating layer 140 to cover the first transfer pattern 1530. The second interlayer insulating layer 150 may contain an insulating material. For example, the second interlayer insulating layer 150 may contain silicon oxide, silicon nitride, silicon oxynitride, aluminum oxide, or the like.

After the second interlayer insulating layer 150 is formed, a second heat treatment process ANL2 may be performed. In an embodiment, the second heat treatment process ANL2 may be performed within a temperature range of 370° C. to about 380° C. for about 10 minutes to about 30 minutes. In other words, after the first transfer pattern 1530 is formed, the second heat treatment process ANL2 may be performed. For example, after forming the second interlayer insulating layer 150 and a contact hole passing through a portion of the second interlayer insulating layer 150, the second heat treatment process ANL2 may be performed.

When the second heat treatment process ANL2 is performed, H moved by the first heat treatment process ANL1 may be more easily adsorbed to the first layer 1531 of the first transfer pattern 1530. Thus, an adsorption distribution of H may be improved, stain defects may be reduced, and a display quality of the display device may be improved.

According to one or more embodiments of the present disclosure, a display device having improved display quality may be implemented by improving a hydrogen adsorption distribution of a transfer pattern connected to a gate electrode of a first thin-film transistor. However, the aspects and features of the present disclosure are not limited thereto.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a first transistor comprising:
a first semiconductor layer on the substrate; and
a first gate electrode on the first semiconductor layer, and at least partially overlapping with the first semiconductor layer;
a second transistor comprising:
a second semiconductor layer on the first gate electrode; and
a second gate electrode on the second semiconductor layer, and at least partially overlapping with the second semiconductor layer;
an insulating structure between the first gate electrode and the second gate electrode; and
a first transfer pattern at a same layer as that of the second gate electrode, the first transfer pattern being electrically connected to the first gate electrode through a contact hole passing through the insulating structure, and comprising a first layer and a second layer on the first layer,
wherein the first layer of the first transfer pattern comprises a first portion in the contact hole, and a second portion outside the contact hole, and
wherein a thickness of the second portion of the first layer is in a range of about 450 Å to 800 Å.

2. The display device of claim 1, wherein a thickness of the first portion of the first layer is in a range of about 200 Å to about 500 Å.

3. The display device of claim 1, wherein a taper angle of the insulating structure is in a range of about 40° to about 75°.

4. The display device of claim 1, wherein a thickness of the second layer is greater than each of a thickness of the first portion of the first layer and the thickness of the second portion of the first layer.

5. The display device of claim 1, wherein the first layer comprises titanium (Ti).

6. The display device of claim 1, further comprising a second transfer pattern on the first transfer pattern, and electrically connecting the first transfer pattern and the second semiconductor layer to each other.

7. The display device of claim 1, further comprising a capacitor electrode between the first gate electrode and the first transfer pattern, and having an opening that overlaps with a portion of the first transfer pattern,
wherein the contact hole overlaps with the opening in the capacitor electrode.

8. The display device of claim 7, wherein the insulating structure comprises:
a first insulating layer between the first gate electrode and the capacitor electrode;
a second insulating layer between the capacitor electrode and the second semiconductor layer; and
a third insulating layer between the second semiconductor layer and the first transfer pattern.

9. The display device of claim 1, wherein the substrate comprises a display area, and a peripheral area outside the display area, and
wherein the display device further comprises a data transfer line bypassing a partial area on the display area, and configured to receive a data signal.

10. The display device of claim 9, wherein the data transfer line comprises:
a first connection line on the second gate electrode, and extending in a first direction; and
a second connection line on the first connection line, and extending in a second direction crossing the first direction, and
wherein the first connection line and the second connection line are electrically connected to each other through a connection contact hole.

11. The display device of claim 10, wherein the first connection line and the second connection line are configured to receive a same data signal as each other.

12. The display device of claim 10, further comprising:
a first input line, a second input line, and a third input line sequentially located in the peripheral area in a direction from an edge of the peripheral area toward a center of the peripheral area;
a first data line connected to the first input line;
a third data line on one side of the first data line, and connected to the third input line; and
a second data line on another side of the first data line, and electrically connected to the second input line through the first connection line and the second connection line.

13. The display device of claim 12, wherein the first connection line is electrically insulated from the first data line, and overlaps with the first data line in at least a partial area.

14. The display device of claim 12, wherein the first data line, the second data line, and the third data line are located at a same layer as that of the second connection line.

15. The display device of claim 1, wherein the first semiconductor layer comprises a silicon semiconductor material.

16. The display device of claim 1, wherein the second semiconductor layer comprises an oxide semiconductor material.

17. A display device comprising:
a substrate;
a first transistor comprising:
a first semiconductor layer on the substrate; and
a first gate electrode on the first semiconductor layer, and at least partially overlapping with the first semiconductor layer;
a second transistor comprising:
a second semiconductor layer on the first gate electrode; and
a second gate electrode on the second semiconductor layer, and at least partially overlapping with the second semiconductor layer;
an insulating structure between the first gate electrode and the second gate electrode; and
a first transfer pattern at a same layer as that of the second gate electrode, and electrically connected to the first gate electrode through a contact hole passing through the insulating structure,
wherein a taper angle of the insulating structure is in a range of about 40° to about 75°.

18. The display device of claim 17, further comprising a second transfer pattern on the first transfer pattern, and electrically connecting the first transfer pattern and the second semiconductor layer to each other.

19. The display device of claim 17, further comprising a capacitor electrode between the first gate electrode and the first transfer pattern, and having an opening that overlaps with a portion of the first transfer pattern,
wherein the contact hole overlaps with the opening in the capacitor electrode.

20. The display device of claim 19, wherein the insulating structure comprises:
a first insulating layer between the first gate electrode and the capacitor electrode;
a second insulating layer between the capacitor electrode and the second semiconductor layer; and
a third insulating layer between the second semiconductor layer and the second gate electrode.

21. The display device of claim 17, wherein the first transfer pattern comprises a first layer, and a second layer on the first layer,
wherein the first layer comprises a first portion in the contact hole, and a second portion outside the contact hole, and
wherein a thickness of the first portion of the first layer is in a range of about 200 Å to about 500 Å.

22. The display device of claim 21, wherein a thickness of the second layer is greater than each of the thickness of the first portion of the first layer and a thickness of the second portion of the first layer.

23. The display device of claim 21, wherein the first layer comprises titanium (Ti).

24. The display device of claim 17, wherein the substrate comprises a display area, and a peripheral area outside the display area, and
wherein the display device further comprises a data transfer line bypassing a partial area on the display area, and configured to receive a data signal.

25. A method of manufacturing a display device, the method comprising:
forming a first transistor comprising:
a first semiconductor layer disposed on a substrate; and
a first gate electrode disposed on the first semiconductor layer to overlap with at least a portion of the first semiconductor layer;
forming a first insulating layer on the first gate electrode;
forming a capacitor electrode on the first insulating layer;
forming a second insulating layer on the capacitor electrode;
forming a second semiconductor layer on the second insulating layer;
forming a third insulating layer on the second semiconductor layer;
forming a contact hole to overlap with the first gate electrode by removing a portion of each of the first insulating layer, the second insulating layer, and the third insulating layer, and then performing a first heat treatment; and
forming, on the third insulating layer, a first transfer pattern that is electrically connected to the first gate electrode through the contact hole.

26. The method of claim 25, wherein, in the forming of the contact hole, a portion of each of the first insulating layer, the second insulating layer, and the third insulating layer is removed so that an insulating structure comprising the first insulating layer, the second insulating layer, and the third insulating layer and having a taper angle in a range of about 40° to about 75° is formed.

27. The method of claim 25, wherein:
the first transfer pattern comprises a first layer, and a second layer on the first layer;
the first layer comprises a first portion outside the contact hole, and a second portion in the contact hole; and
a thickness of the first portion of the first layer is in a range of about 200 Å to about 500 Å.

28. The method of claim 27, wherein a thickness of the second portion of the first layer is in a range of about 450 Å to about 800 Å.

29. The method of claim 25, further comprising performing a second heat treatment after the forming of the first transfer pattern.
